(19) United States
(12) Patent Application Publication
(10) Pub. No.: US 2023/0235458 A1
(43) Pub. Date: Jul. 27, 2023

(54) SHOWERHEAD WITH REDUCED INTERIOR VOLUMES

(71) Applicant: Lam Research Corporation, Fremont, CA (US)

(72) Inventor: Joseph Edgar Morgan, Tigard, OR (US)

(21) Appl. No.: 18/002,616

(22) PCT Filed: Jul. 22, 2021
(86) PCT No.: PCT/US2021/042839

§ 371 Date: Dec. 20, 2022

Related U.S. Application Data
(60) Provisional application No. 62/706,000, filed on Jul. 24, 2020.

(51) Int. Cl. C23C 16/455; H01J 37/32

(52) U.S. Cl. CPC C23C 16/45565; H01J 37/32449

(57) ABSTRACT

Additively manufactured showerheads for semiconductor processing operations are disclosed that may have various features enabled by the use of such manufacturing techniques. In some implementations, such showerheads may have multiple independent flow paths featuring transverse passages arranged to form a rhombic lattice pattern and gas distribution ports and/or riser passages that are located at various intersections between such transverse passages. Such showerheads may also include features that improve their manufacturability while providing desired gas flow performance. For example, the cross-sections of the transverse passages may be designed such that they are generally triangular or pentagonal in shape, which may allow for more efficient use of available material volume within the showerhead for the purposes of providing gas flow passages while also providing geometries that take into account the limitations of typical additive manufacturing processes that may be used.

### RELATED APPLICATION(S)

A PCT Request Form is filed concurrently with this specification as part of the present application. Each application that the present application claims benefit of or priority to as identified in the concurrently filed PCT Request Form is incorporated by reference herein in its entirety and for all purposes.

### BACKGROUND

Semiconductor processing tools commonly use a “showerhead” to distribute semiconductor processing gases across a substrate or wafer that is supported within a semiconductor processing chamber by a pedestal or chuck. Showerheads typically feature a large number of gas distribution ports that are distributed across the underside of the showerhead and through which processing gases are flowed during semiconductor processing operations. There are two general classes of showerheads used in semiconductor processing tools—“chandelier” type showerheads and “flush-mount” showerheads. Chandelier-type showerheads typically include a disk-like structure housing the gas distribution ports, one or more internal plenums for distributing processing gases to those gas distribution ports, and a stem that connects to or extends from a top side of the disk-like structure and up to or through a ceiling of the processing chamber in which the chandelier-type showerhead is located. The stem supports the disk-like structure within the processing chamber and also acts to route processing gases to the plenum(s) within the disk-like structure. A flush-mount showerhead does not have a stem or equivalent structure, and instead is simply mounted, for example, to the walls of the semiconductor processing chamber, often, in effect, acting as the lid to the semiconductor processing chamber.

Presented herein is a design for an additively manufactured semiconductor processing showerhead.

### SUMMARY

Details of one or more implementations of the subject matter described in this specification are set forth in the accompanying drawings and the description below. Other features, aspects, and advantages will become apparent from the description, the drawings, and the claims.

The present inventor conceived of an additively manufactured showerhead. Such a showerhead may be manufactured, for example, using any suitable additive manufacturing technique, such as selective laser melting (SLM) (which may be used to produce ceramic or silicon versions thereof) or direct metal laser melting (DMLM) (which may be used to produce metal versions thereof).

In most additive manufacturing processes, a part is manufactured by adding material to the part one horizontal layer at a time; such layers may be extremely thin, e.g., 0.02 mm at a time is possible for DMLM parts. In DMLM, for example, a platen supporting a part is gradually lowered relative to a reference plane. The platen forms the “floor” of a cavity that is used to contain the part being manufactured. Each time the platen is lowered, powdered material is added to the cavity and then leveled so as to be level with the reference plane. A laser then scans across the reference plane and applies heat to the uppermost layer of powdered material in the regions where structure is desired, melting the powder granules to each other and to any underlying, previously fused structure. Once a particular layer is done, the platen may be lowered slightly, a new layer of powdered material may be applied, and the laser melting process repeated. This process is repeated until the part is complete, at which point the cavity of the DMLM device will be filled with unmelted powdered material having buried within it the additively manufactured component.

Such additively manufactured components typically have a very fine grain microstructure as compared with bulk-manufactured components (e.g., such as components made by casting in which molten material is formed into the desired component in generally a single operation as opposed to a small number of grains being fused together at a time over the course of many sequential operations as is done in SLM or DMLM)), i.e., a structure that is formed through the fusion of small grains of solid material through the selective application of heat provided by a laser. Such additively manufactured components also, in many cases, tend to have a microstructure that is noticeably directional, with micrograins having profiles in the XY plane that are more rounded and larger than the profiles of such micrograins in a plane parallel to the Z direction (with the XY plane corresponding to the horizontal plane, and the Z direction corresponding to the vertical direction, relative to the component as positioned during the additive manufacturing process). FIG. 1, for example, shows representational grain boundaries taken in a vertical plane (left side) and horizontal plane (right side) in an example component made using one example DMLM process; as can be seen, the size of the grains in the vertical plane exhibit a high degree of asymmetry with respect to their size in the Z-direction compared to their size in either the X or Y directions. The micrograins tend to be much longer in the X and/or Y directions than they are thick in the Z direction. This micrograin structure may be referred to herein as being an anisotropic micrograin structure, which should be understood to differentiate it from micrograin structures in which the micrograins, while exhibiting variation in size and shape, do not generally exhibit dimensional variance that is tied to a particular axis. It will be understood that at least some of the additively manufactured showerheads discussed herein may exhibit such anisotropic micrograin structure.

The use of such additive manufacturing techniques permits the adoption of showerhead geometries that would be extremely difficult or impossible to achieve using only conventional machining (subtractive machining) techniques such as milling, drilling, or turning. Such showerhead geometries may allow, for example, showerheads to have smaller interior volumes (thus decreasing the amount of gas needed to provide a desired gas flow through the showerhead and reducing the amount of time needed before the showerhead reaches steady state flow) and, in some cases, an increased number of different fluidically isolated flow paths within the showerhead (or at least a higher density of such flow paths).

Typical semiconductor showerheads are generally circular in shape and have one or more fluidic inlets located near the center of the showerhead; the fluidic inlet typically provides gas to a large, flat cylindrical plenum volume within the showerhead, and the gas is then flowed out of the showerhead through a plurality of gas distribution ports that are in fluidic communication with the plenum volume. When gas flow is initiated with such a showerhead, there may be some delay before a desired level of gas flow is achieved through the gas distribution ports, as the plenum volume may be quite large, e.g., orders of magnitude larger than, compared to the volume of the gas distribution ports.

In contrast, the additively manufactured showerheads disclosed herein replace the large, generally cylindrical plenum volumes typically found in conventional showerheads with a network of transverse passages that act to distribute the gas delivered through the fluidic inlet to the plurality of gas distribution ports located on the underside of the showerhead. Since additive manufacturing techniques allow for true double-blind passages or holes to be easily made, such showerheads may have a large number of such transverse passages that are completely contained within the showerhead body without incurring additional manufacturing cost (in fact, the manufacturing cost of such showerheads may somewhat paradoxically decrease as the number of transverse passages in an additively manufactured showerhead increases due to the increased amount of “open volume” within the part as compared with “solid volume”). For clarity, a double-blind hole or passage is a hole or passage that does not extend along the hole or passage axis to an opening on an exterior surface of the component that contains it (in contrast, a blind hole is a hole that extends into a part from a single opening on an exterior surface of that part, while a through-hole is a hole that extends between two openings on exterior surfaces of a part). While double-blind holes can be made using traditional machining techniques, such as drilling, such double-blind holes must first be made by drilling a blind hole and are then turned into double-blind holes by filling in the top of the hole with a plug, e.g., that is welded, brazed, or otherwise fixed in place. Such multi-stage double-blind hole techniques, however, are costly and introduce an increased potential for leakage at the plug/hole interface. Another technique that may be used to produce double-blind holes or passages in a part is to make a laminated part in which the double-blind hole is milled into the mating face of one or two mating layers and the layers are then bonded together, e.g., brazed. Such techniques, however, may be difficult to implement for small-thickness layers, require additional (costly) manufacturing steps, and may also have issues with potential leak paths at the inter-layer bond interface locations.

The present inventor realized that using additive manufacturing to create a showerhead allowed for the adoption of complex double-blind transverse passage arrangements within the body of the showerhead. The present inventor further realized that such arrangements could be leveraged to provide for multiple independent flow paths through the showerhead that all generally had the same flow characteristics. In particular, showerheads supporting two, three, four, or even more independent flow paths could be provided using such techniques.

In addition to such benefits, the present inventor further determined that particular cross-sectional geometries could be used with such transverse passages to improve the manufacturability of such transverse passages using additive manufacturing techniques while still providing a sufficiently efficient usage of available material volume within the showerhead.

For example, if there is no underlying previously melted structure in a particular area being melted during a layer’s creation, the newly melted layer may only be supported by unmelted powdered material and may experience some collapse or other defect that reduces its quality in that area. To avoid such defects, it is common for DMLM parts to also include temporary support structures that can be used to reduce the size of the unsupported areas (and thus reduce or eliminate such defects) but can easily be broken off or otherwise removed after the part is complete. The use of temporary supports, however, is not feasible in the context of the internal double-blind passages discussed herein since there is no way to remove such supports from within the part after it is made.

The present inventor instead determined that using transverse passages with generally flat bottoms and angled or gabled tops could avoid the manufacturing issues discussed above while still providing efficient use of the volume available for such transverse passages.

While various implementations of additively manufactured showerheads will be evident from the above discussion and the discussion below, the present disclosure includes at least the following specific implementations, which are provided for clarity but are not intended to be limiting.

In some implementations, an apparatus may be provided that includes a showerhead body having one or more sets of first transverse passages extending along paths that may be generally parallel to a first plane, a set of first gas distribution ports extending along paths that may be generally perpendicular to the first plane and having first ends that terminate within the showerhead body and second ends terminating at a first exterior surface of the showerhead body, and one or more first fluidic inlets. In such implementations, the one or more sets of first transverse passages may include a first set of first transverse passages, the first set of first transverse passages may be fluidically interposed within the showerhead body between the set of first gas distribution ports and the one or more first fluidic inlets, and the first set of first transverse passages may include at least one first transverse passage having a cross-section such as a nominally triangular cross-section or a nominally pentagonal cross-section.

In some such implementations, the showerhead body may be additively manufactured and may have an anisotropic micrograin structure resulting from the additive manufacturing process.

In some implementations, there may be two or more sets of first transverse passages, the two or more sets of first transverse passages may further include a second set of first transverse passages, the showerhead body may further include one or more sets of first riser passages extending along paths that may be generally perpendicular to the first plane, each set of first riser passages may be fluidically interposed between two of the sets of first transverse passages, and the one or more sets of first riser passages may include a first set of first riser passages fluidically interposed between the first and second sets of first transverse passages.

In some implementations, each first riser passage in the first set of first riser passages may be extension of a corresponding one of the first gas distribution ports.

In some implementations, the at least one first transverse passage in the first set of first transverse passages may have a nominally triangular cross-section. In some such implementations, the nominally triangular cross-section may have a first side that is generally parallel to the first plane and second and third sides that each form an included angle of 45° or more with the first side.

In some other implementations, the at least one first transverse passage in the first set of first transverse passages may have a nominally pentagonal cross-section. In some such implementations, the nominally pentagonal cross-section may be a pentagon with a first side that is generally parallel to the first plane, second and third sides that are each adjacent to the first side and generally perpendicular to the first plane, and fourth and fifth sides that may be, respectively, adjacent to the second and third sides and that each form an angle of 45° or more with respect to the first side.

In some implementations, the first gas distribution ports may be arranged in a non-orthogonal rhombic lattice pattern.

In some implementations, the non-orthogonal rhombic lattice pattern may have a maximum pitch along a first axis and a minimum pitch along a second axis perpendicular to the first axis, and the maximum pitch may be generally twice the minimum pitch.

In some implementations, the first transverse passages in the first set of first transverse passages may be arranged in two first linear arrays, each first linear array may include a different plurality of the first transverse passages in the first set of first transverse passages, the first transverse passages in each first linear array may be generally parallel to one another, and each point of intersection between first transverse passages in the first set of first transverse passages may align with a corresponding one of the first gas distribution ports.

In some implementations, the showerhead body may further include one or more sets of second transverse passages extending along paths that may be generally parallel to the first plane, a set of second gas distribution ports extending along paths that may be generally perpendicular to the first plane and having first ends that terminate within the showerhead body and second ends terminating at the first exterior surface of the showerhead body, and one or more second fluidic inlets. In such implementations, the one or more sets of second transverse passages may include a first set of second transverse passages, and the first set of second transverse passages may be fluidically interposed within the showerhead body between the set of second gas distribution ports and the one or more second fluidic inlets.

In some further such implementations, the showerhead body may further include one or more sets of third transverse passages extending along paths that may be generally parallel to the first plane, a set of third gas distribution ports extending along paths that may be generally perpendicular to the first plane and having first ends that terminate within the showerhead body and third ends terminating at the first exterior surface of the showerhead body, and one or more third fluidic inlets. In such implementations, the one or more sets of third transverse passages may include a first set of third transverse passages, and the first set of third transverse passages may be fluidically interposed within the showerhead body between the set of third gas distribution ports and the one or more third fluidic inlets.

In some such implementations, the showerhead body may further include one or more sets of fourth transverse passages extending along paths that may be generally parallel to the first plane, a set of fourth gas distribution ports extending along paths that may be generally perpendicular to the first plane and having first ends that terminate within the showerhead body and fourth ends terminating at the first exterior surface of the showerhead body, and one or more fourth fluidic inlets. In such implementations, the one or more sets of fourth transverse passages may include a first set of fourth transverse passages, and the first set of fourth transverse passages may be fluidically interposed within the showerhead body between the set of fourth gas distribution ports and the one or more fourth fluidic inlets.

In some such implementations, the first, second, third, and fourth gas distribution ports may be arranged in respective first, second, third, and fourth non-orthogonal rhombic lattice patterns, each of the first, second, third, and fourth non-orthogonal rhombic lattice patterns may have a maximum pitch along a corresponding first axis and a minimum pitch along a second axis, and the first, second, and third non-orthogonal rhombic lattice patterns may each be respectively offset along the first axis from the second, third, and fourth non-orthogonal rhombic lattice patterns by a distance of one quarter of the maximum pitch.

In some implementations, the apparatus may further include a stem portion. In such implementations, the stem portion may extend from a side of the showerhead body opposite the first exterior surface and may include one or more first fluidic inlet passages fluidically connected with the one or more first fluidic inlets, one or more second fluidic inlet passages fluidically connected with the one or more second fluidic inlets, one or more third fluidic inlet passages fluidically connected with the one or more third fluidic inlets, and one or more fourth fluidic inlet passages fluidically connected with the one or more fourth fluidic inlets.

In some such implementations, the one or more first fluidic inlet passages may encircle the one or more second fluidic inlet passages, the one or more second fluidic inlet passages may encircle the one or more third fluidic inlet passages, and the one or more third fluidic inlet passages may encircle the one or more fourth fluidic inlet passages.

In some additional or alternative such implementations, the stem portion may further include a first fluidic inlet port, the one or more first fluidic inlet passages may include a first annular fluidic inlet passage, the first annular fluidic inlet passage may extend along a first axis and have a generally annular cross-section, the first annular fluidic inlet passage may be fluidically interposed between the first fluidic inlet port and the one or more fluidic inlets, and a flow divider structure may be positioned within the first annular fluidic inlet passage such that a first plane is coplanar with the first axis, passes through the first fluidic inlet port, and passes through the flow divider.

In some such implementations, the flow divider structure may have a cross-section, when viewed along an axis perpendicular to the first axis, having a lachrymiform shape or a triangular shape.

In some other or alternative such implementations, surfaces of the flow divider structure facing towards the showerhead body may all be angled at 45° or more, or such that planes tangent to those surfaces are at 45° or more, from the first plane.

### BRIEF DESCRIPTION OF THE DRAWINGS

FIG. 1 depicts two diagrams of example micrograin structures for an example additively manufactured component.

FIG. 2 depicts a perspective view of an example showerhead for use in semiconductor processing systems.

FIG. 3 depicts an exploded perspective view of the example showerhead of FIG. 2.

FIG. 4 depicts a perspective view of an example manifold for the example showerhead of FIG. 2.

FIG. 5 depicts a cutaway perspective view of the example manifold of FIG. 4.

FIG. 6 depicts a bottom view of the example showerhead of FIG. 2.

FIG. 7 depicts a side section view of the example showerhead of FIG. 2.

FIG. 8 depicts a top view of the flow paths within the example showerhead of FIG. 2.

FIG. 9 depicts a perspective view of the flow paths within the example showerhead of FIG. 2.

FIG. 10 depicts a perspective section view of the flow paths within the example showerhead of FIG. 2.

FIGS. 11 and 12 depict simplified schematic views of two flow divider arrangements

FIGS. 13 through 16 depict perspective section views of first, second, third, and fourth flow paths, respectively, of the flow paths within the example showerhead of FIG. 2.

FIG. 17 depicts a perspective view of another example showerhead having various features disclosed herein.

FIG. 18 depicts a perspective section view of the example showerhead of FIG. 17.

FIG. 19 depicts a perspective view of the flow paths within the example showerhead of FIG. 18.

FIGS. 20 through 23 depict perspective section views of first, second, third, and fourth flow paths, respectively, of the flow paths within the example showerhead of FIG. 18.

FIG. 24 depicts an isometric view of a plurality of flow paths for an example showerhead; FIGS. 24-A through 24-D depict isometric views of each flow path of FIG. 24 in isolation.

FIG. 25 provides a detail view of a portion of sets of transverse passages.

FIG. 26 provides a detail plan view of the transverse passages for a single flow path for the implementation of FIG. 25.

FIG. 27 depicts an example of a rhombic lattice pattern that may be used for a dual-flow path showerhead.

FIG. 28 depicts an example of a rhombic lattice pattern that may be used for a triple-flow-path showerhead.

FIG. 29 depicts a schematic of an example dual-flow showerhead according to the concepts discussed herein.

FIG. 30 depicts a cross-section of flow paths for an example showerhead.

FIG. 31 depicts an isometric view of the flow paths of FIG. 30.

FIG. 32 depicts four example cross-sections that were considered for use in additively manufactured showerheads.

FIG. 33 depicts similar cross-sectional shapes as in FIG. 32, but in the context of a reduced-height frame, e.g., a rectangular area that is 1 ×0.5 units in size.

FIG. 33′ depicts a cross section of transverse passages depicted in FIG. 2 and FIG. 17.

FIG. 34 depicts example triangular and pentagonal cross-sections.

FIG. 35 depicts views of an example showerhead made using subtractive machining.

FIG. 36 depicts a schematic of an example semiconductor processing chamber.

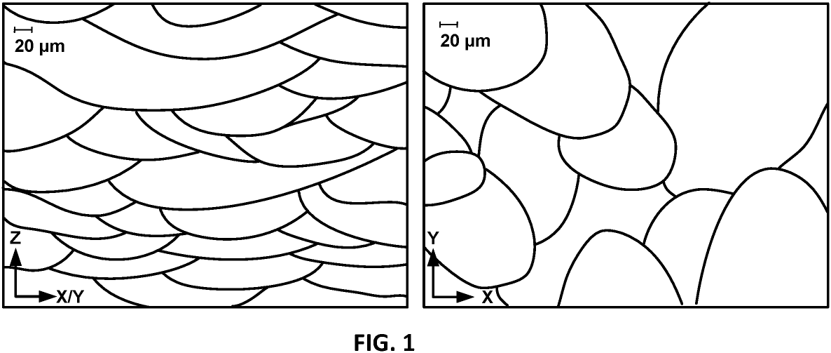

It will be appreciated that the Figures discussed herein are merely intended to provide a reference for discussion and are not intended to limit the present disclosure. Other implementations not specifically depicted herein but evident from the totality of the disclosure are also intended to be within the scope of the disclosure.

### DETAILED DESCRIPTION

While the particular showerhead geometries and features discussed herein were conceived of in the context of additively manufactured showerheads, e.g., showerheads made using selective laser melting or direct metal laser melting, it will be understood that showerheads featuring such geometries or features but made using other techniques, including the use of traditional subtractive machining techniques, are also considered within the scope of this disclosure.

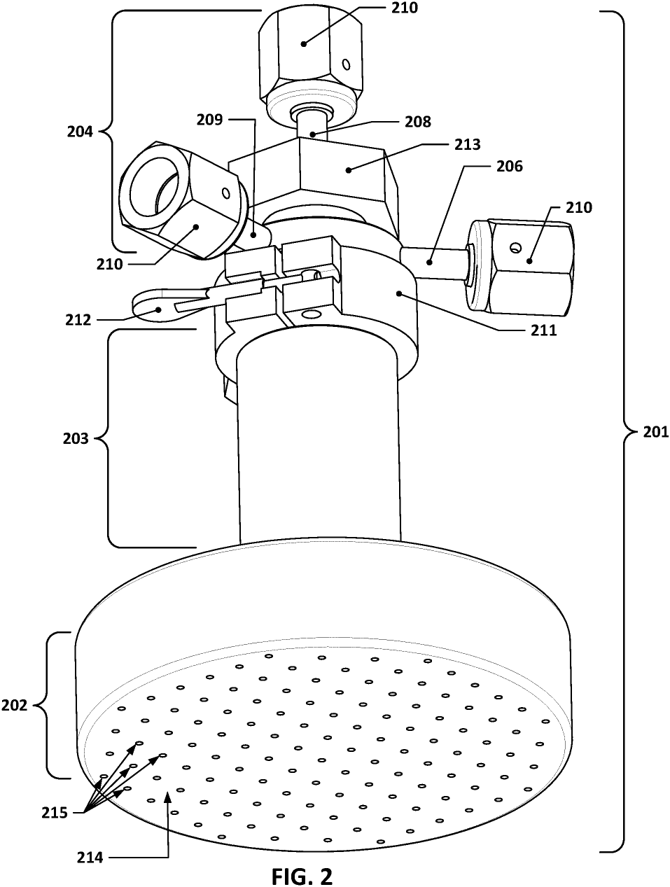

FIG. 2 depicts a perspective view of an example showerhead for use in semiconductor processing systems. As seen in FIG. 2, a showerhead 201 may have a showerhead body 202, a stem portion 203, and a manifold 204. The showerhead 201 is a chandelier-type showerhead, but other implementations may be flush-mount showerheads and may reduce the size of the stem portion 203 or even omit it entirely.

It will be understood that in FIG. 2, as well as in other Figures herein, the showerhead body 202 that is depicted is reduced in diameter/size relative to the other features shown so as to allow for the other features, some of which are typically quite small in relationship to the showerhead body 202, to be more easily seen in the context of the showerhead body 202 within the constraints of the drawing page size. It will be further understood that the showerhead body 202 may, in actual practice, be considerably larger in diameter, e.g., two or three times or more as large, than as depicted in FIG. 2. It will be further understood that the internal features of the showerhead body 202 may be replicated as needed or desired commensurate with any increased size of the showerhead body 202.

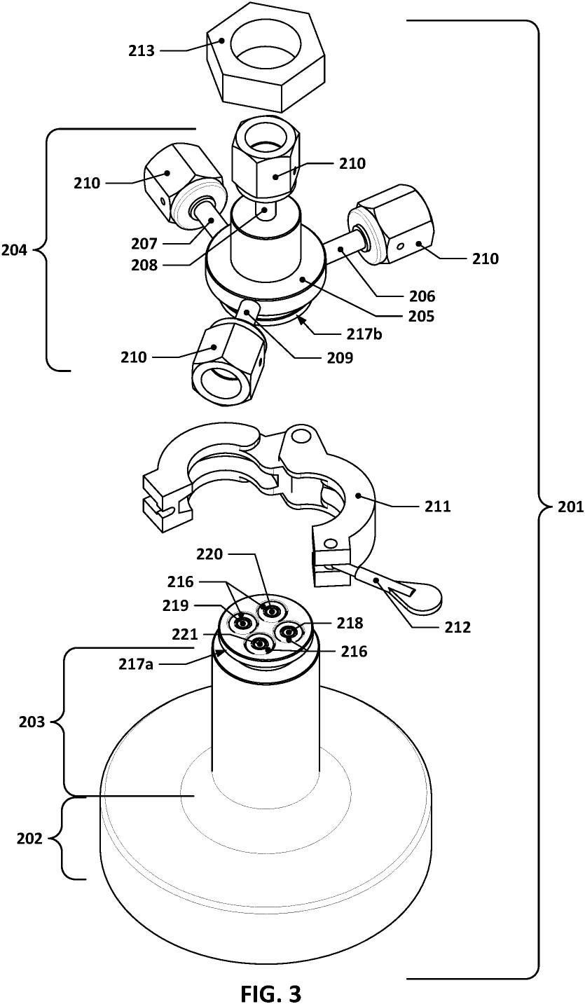

The manifold 204 of the showerhead 201 includes, in this example, four separate gas inlets that extend from (and into) a manifold body 205. For example, a first gas inlet 206, a second gas inlet 207, and a third gas inlet 208 may be provided as shown, with gas flow paths that are primarily radial in nature (or somewhat radial in nature), and a fourth gas inlet 209 may be provided that has a flow path that is primarily axial in nature, e.g., primarily flowing in a direction parallel to a center axis of the stem portion 203. Each of the first, second, third, and fourth gas inlets 206-209 (the second gas inlet 207 is not visible here, but see FIG. 3) may have a fitting 210 at one end to facilitate coupling thereof to an appropriate gas supply line. It will be appreciated that other implementations may feature other arrangements of gas inlets and/or fittings.

The manifold body 205 may be coupled to the stem portion 203 through any of a variety of mechanisms and may, in some instances, simply be an extension of the stem portion 203 or of the showerhead body 202. In the depicted arrangement, the manifold body 205 and the stem portion 203 may both have circumferential tapered flanges that may be captured via a clamp 211. The clamp 211 may, for example, be a split-collar clamp that may be tightened through tightening mechanism 212.

The manifold body 205, as shown in FIG. 2, may also feature a threaded portion and a fixturing nut 213 that may be threaded thereonto. Such a feature may, for example, be used to affix the showerhead 201 to a fixture or other hardware that may support the showerhead 201 relative to the processing chamber within which it is installed. For example, the supporting hardware may have a hole that is sized large enough for the threaded portion of the manifold body 205 to be passed through, and the fixturing nut 213 may then be threaded onto the portion of the manifold body 205 that extends through the supporting hardware and tightened, thereby clamping the supporting hardware between the fixturing nut 213 and the manifold body 205.

The showerhead body 202, as shown in FIG. 2, also has a first exterior surface 214, e.g., the underside of the showerhead body 202 when the showerhead 201 is in an installed and in-use configuration, that has a plurality of gas distribution ports 215 extending therethrough. Each gas distribution port may have a first end that terminates at a location somewhere within the showerhead body 202, e.g., at a corresponding transverse passage, and a second end that terminates at the first exterior surface, e.g., at openings in the first exterior surface.

FIG. 3 depicts an exploded perspective view of the example showerhead of FIG. 2. In FIG. 3, it can be seen how the fixturing nut 213 may be removed from the manifold body 205. The second gas inlet 207 is also visible in FIG. 3, as are tapered flanges 217a and 217b, as well as first, second, third, and fourth fluidic inlet ports 218-221 of the stem portion 203.

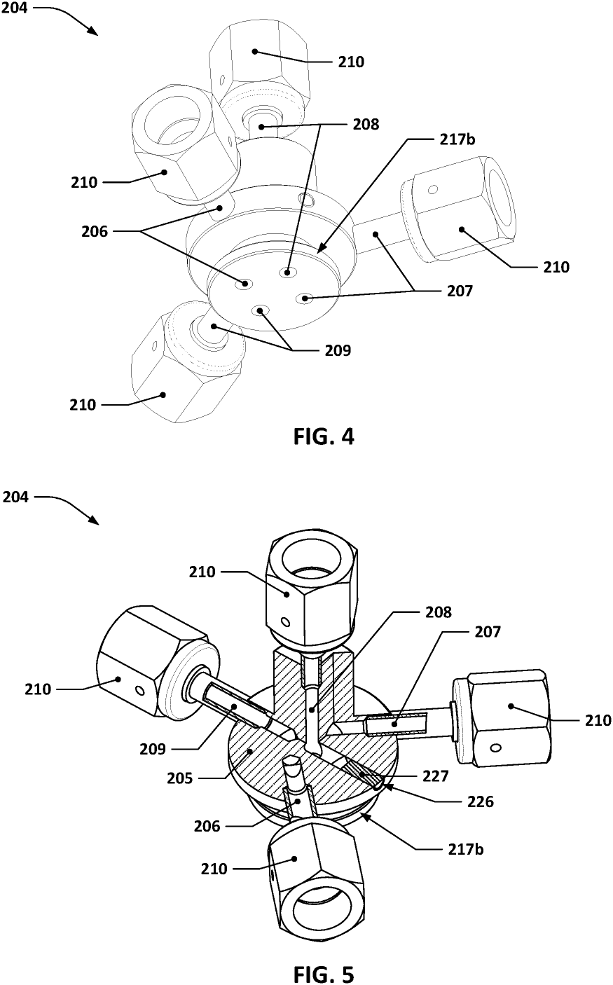

While any suitable manifold 204 may be used, the manifold 204 shown in FIGS. 2 and 3 may provide a relatively compact system for providing multiple gas flows to the showerhead 201. FIG. 4 depicts a perspective view of the example manifold for the example showerhead of FIG. 2, whereas FIG. 5 depicts a cutaway perspective view of the example manifold of FIG. 4.

As can be seen in FIG. 4, the four gas inlets 206-209 may each terminate at a different hole on the underside of the manifold body 205, i.e., the surface of the manifold body 205 that buts up against the stem portion 203 when the showerhead 201 is fully assembled. Each such hole may align with a corresponding fluidic inlet port 218-221 on the top surface of the stem portion 203 (or on the top surface of the showerhead body 202 when used with a flush-mount showerhead) and may be used to provide gas thereto. An O-ring 216 may be used to provide a seal between each fluidic inlet port 218-221 and each gas inlet 206-209.

As shown in FIG. 5, the manifold body 205 may have a hole drilled into the top along a vertical axis to form part of the third gas inlet 208; a tube stub, which may also be referred to in the industry as a gland, with one of the fittings 210 may be inserted into this hole and welded or brazed into place. For clarity, references to “vertical” and “horizontal” in this disclosure are, unless otherwise indicated through context, made with reference to the horizontal and vertical directions when the showerhead is in an in-use configuration, e.g., with the first exterior surface 214 facing downwards towards a semiconductor substrate being subjected to processing operations. The remaining first, second, and fourth gas inlets 206, 207, and 209 may be provided by holes that are drilled in horizontal directions at different circumferential locations about the manifold body 205. Tube stubs with fittings 210 may be similarly inserted into those holes and brazed, welded, or otherwise fixed into place in a leakproof manner. Each of the first, second, and fourth gas inlets 206, 207, and 209 may extend in a horizontal direction into the manifold body 205 until they reach a corresponding vertical hole that leads to the underside of the manifold body 205. In the example provided, these fluidic inlet ports are arranged in a “Y” shape, although other arrangements are possible as well (for example a Y-shape with equal length arms and equal angles between arms, or a four-armed cross arrangement in which the third fluidic inlet 208 is horizontal like the first, second, and fourth through third gas inlets 206, 207, and 209. The third fluidic inlet port 208 in this example follows a somewhat more complicated path since the majority of the third fluidic inlet port 208 is provided by a vertical hole that is centered on the center axis of the manifold body 205 while the hole on the underside of the manifold body 205 that is fluidically connected with that vertical hole is, like the other three holes on the underside of the manifold body 205, radially offset from the center axis of the manifold body 205. To provide for this offset, a radial hole 226 is drilled into the exterior of the manifold body such that it intersects both vertical holes for the third fluidic inlet port 208; a plug 227 is then inserted into the portion of the radial hole that spans between the exterior surface of the manifold body 205 and the radially outermost hole and welded or brazed into place to prevent leakage past the plug. The manifold body 205 may also be manufactured using additive manufacturing techniques, if desired, in which case the flow paths may take other shapes and the use of a plug to create a double-blind passage may be avoided.

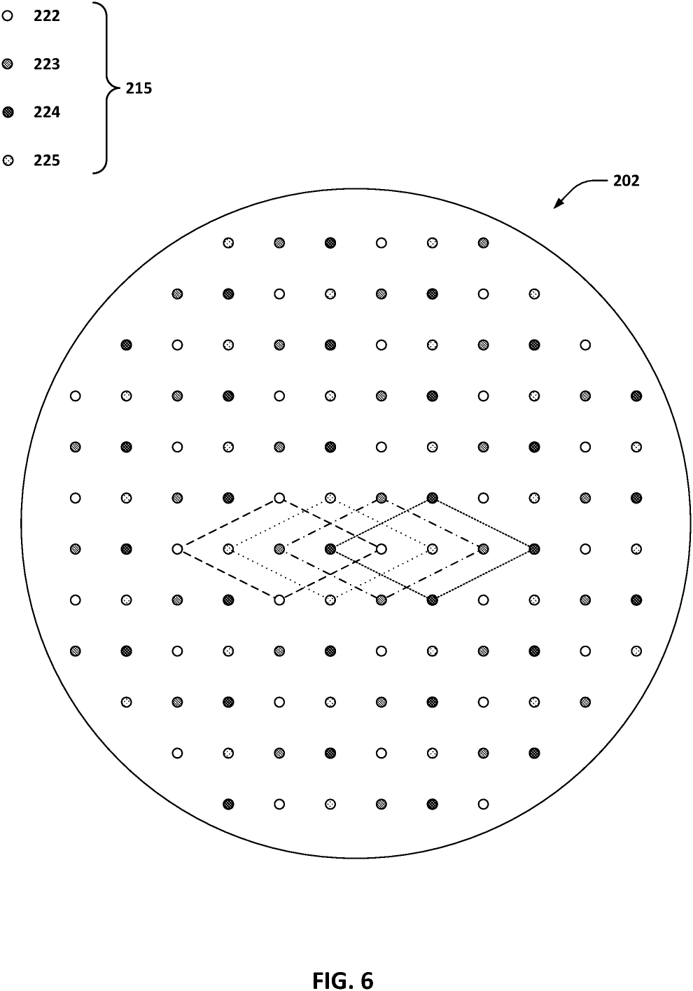

The showerhead 201 may generally appear, aside from potentially the manifold 204, to be similar to existing showerheads. However, due to the internal arrangements of flow paths that may be incorporated into such showerheads, the arrangement of the gas distribution ports 215 on the first exterior surface 214 may be very different than is typically provided. For example, in FIG. 6, which depicts a bottom view of the example showerhead of FIG. 2, it can be seen that the gas distribution ports 215 include four different subsets of gas distribution ports: first gas distribution ports 222, second gas distribution ports 223, third gas distribution ports 224, and fourth gas distribution ports 225. As is further apparent from FIG. 6, the gas distribution ports 215 in each subset of gas distribution ports 215 are arranged in a rhombic lattice pattern, e.g., with gas distribution ports 215 positioned at intersection points within a rhombic lattice patter. A rhombic lattice pattern is a pattern in which pattern instances are generally positioned at the intersections between a first set of parallel lines and a second set of parallel lines. The lines in both the first and second sets of lines are spaced the same distance apart from one another, and the lines in the first set of lines are not parallel to the lines in the second set of lines. In the present example, the rhombic lattice pattern is a non-orthogonal lattice pattern, i.e., the lines in the first set of lines are not orthogonal to the lines in the second set of lines (an orthogonal lattice pattern would be a square grid or square array). FIG. 6 includes depictions of four rhombuses that generally show the rhombic arrangement of each of the four sets of gas distribution ports 215.

The smallest rhombus that may be drawn with vertices that are each coincident with a different pattern instance in a rhombic lattice pattern may generally be characterized as being the unit rhombus for the rhombic lattice pattern. The unit rhombus may generally be defined as having a maximum pitch along a first axis and a minimum pitch along a second axis perpendicular to the first axis (in an orthogonal rhombic lattice pattern, the minimum and maximum pitches may be equal). The maximum pitch refers to the maximum distance between vertices of the unit rhombus, and the minimum pitch refers to the minimum distance between vertices of the unit rhombus. In some implementations discussed herein, the maximum pitch may be twice the minimum pitch. As will become apparent from later discussion, the rhombic lattice patterns used for each flow path in various implementations discussed herein may be arranged in a staggered fashion, when viewed along a direction perpendicular to the planes in which the rhombic lattice patterns are arranged, along the first axis. For example, in a dual flow-path showerhead, the two sets of rhombic lattice patterns may be staggered by a distance of one half of the maximum pitch along the first axis. Similarly, in a triple or quad flow-path showerhead, the sets of rhombic lattice patterns may be staggered apart from each other by a distance of one third or one quarter of the maximum pitch, respectively.

It will be noted from FIG. 6 that the gas distribution ports for the four flow paths in this particular example are arranged in a square pattern that repeats itself in an offset manner. For example, there may be four gas distribution ports, one from each flow path, defining a square. Each set of four such gas distribution ports may be offset along one axis (aligned with a side of the square) by the length of one of the square sides, thereby causing the square patterns to be offset relative to each other.

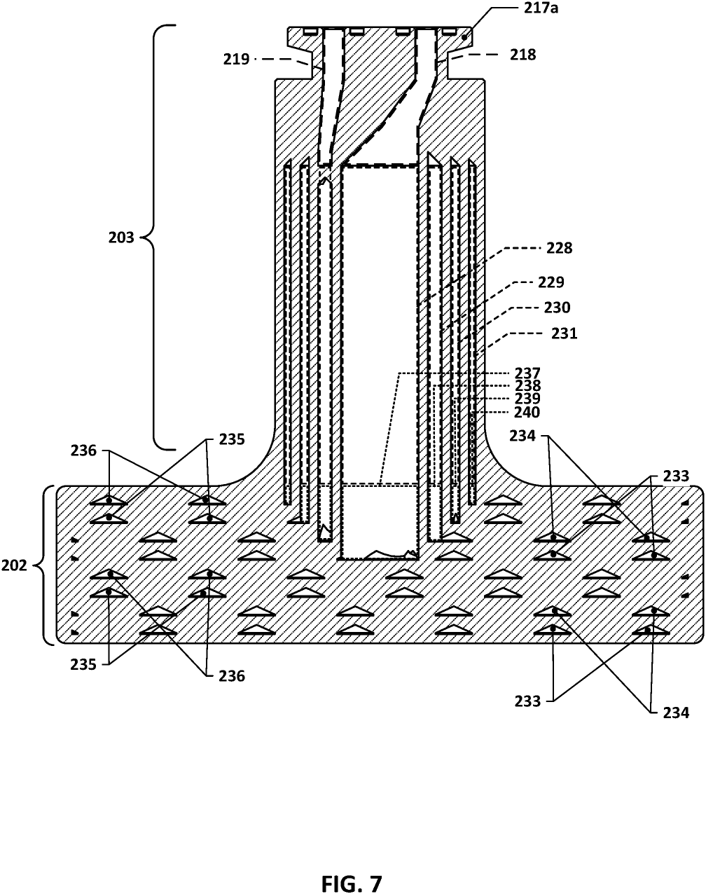

FIG. 7 depicts a side section view of the example showerhead of FIG. 2. As can be seen in FIG. 7, the stem portion 203 may have a plurality of fluidic inlet passages extending from one end thereof to the other, e.g., first, second, third, and fourth fluidic inlet passages 228-231. In this example, each fluidic inlet passage 228-31 is generally annular in nature, e.g., defined between two (or defined by one) generally annular walls, with the second fluidic inlet passage 229 encircling the first fluidic inlet passage 228, the third fluidic inlet passage 230 encircling the second fluidic inlet passage 229, and the fourth fluidic inlet passage 231 encircling the third fluidic inlet passage 230. In other implementations, other arrangements of fluidic inlet passages may be used, e.g., concentric rings of circularly arrayed non-annular fluidic inlet passages, or even non-concentrically arranged fluidic inlet passages, e.g., four fluidic inlet passages arranged in a square pattern, similar to the underside of the manifold 204.

Regardless of the particular arrangement of fluidic inlet passages, each fluidic inlet passage 228-231 may be fluidically connected with a corresponding one of the fluidic inlet ports 218-221. It will be understood that in implementations in which the manifold 204 is integrated into the stem portion 203, the fluidic inlet ports 218-221 and the gas inlets 206-209 may be provided by the same features. Similarly, in flush-mount implementations with no stem portion 203, the fluidic inlet passages 228-231 may be provided by whatever fluidic conduits exits between the gas inlets 206-209 and features within the showerhead body 202.

In FIG. 7, the first fluidic inlet port 218 is shown as fluidically connected with the first fluidic inlet passage 228, which extends down to the showerhead body 202 and is fluidically connected with a first fluidic inlet 237. The first fluidic inlet 237, in this example, is a portion of the first fluidic inlet passage 228 that extends out of the stem portion 203 and into the showerhead body 202. Similarly, the second fluidic inlet port 219 is shown as fluidically connected with the second fluidic inlet passage 229, which extends down to the showerhead body 202 and is fluidically connected with a second fluidic inlet 238. The second fluidic inlet 238, in this example, is similarly a portion of the second fluidic inlet passage 229 that extends out of the stem portion 203 and into the showerhead body 202, although to a lesser depth than the first fluidic inlet 237. The third and fourth fluidic inlet passages 230 and 231, similarly, may each respectively be fluidically interposed between the third and fourth fluidic inlet ports 220 and 221 and the third and fourth fluidic inlets 239 and 240.

Each of the first through fourth fluidic inlets 237 through 240 may, in turn, be fluidically connected with one or more respective sets of transverse passages, such as sets of transverse passages including first through fourth transverse passages 233 through 236. The transverse passages may extend along paths that are generally parallel to a first plane, e.g., a plane that is horizontal when the showerhead is installed and in an in-use configuration. The gas distribution ports, in contrast, may extend along directions perpendicular to the first plane (although in some implementations, the gas distribution ports may be at an oblique angle with respect to the first plane).

In the depicted example, for example, the first fluidic inlet 237 is fluidically connected with two corresponding sets of first transverse passages 233, with one set being positioned at an elevation generally corresponding with the bottom of the first fluidic inlet 237, and the other set being positioned lower in the showerhead body 202 in a position proximate the first exterior surface 214. Similarly, the second fluidic inlet 238 is fluidically connected with two corresponding sets of second transverse passages 234, with one set being positioned at an elevation generally corresponding with the bottom of the second fluidic inlet 238 and the other set being positioned just above the lower set of first transverse passages 233.

The third fluidic inlet 239 may similarly be fluidically connected with two corresponding sets of third transverse passages 235, with one set being positioned at an elevation generally corresponding with the bottom of the third fluidic inlet 239 and the other set being positioned just above the lower set of second transverse passages 234. The fourth fluidic inlet 2340 may similarly be fluidically connected with two corresponding sets of fourth transverse passages 236, with one set being positioned at an elevation generally corresponding with the bottom of the fourth fluidic inlet 240 and the other set being positioned just above the lower set of third transverse passages 235.

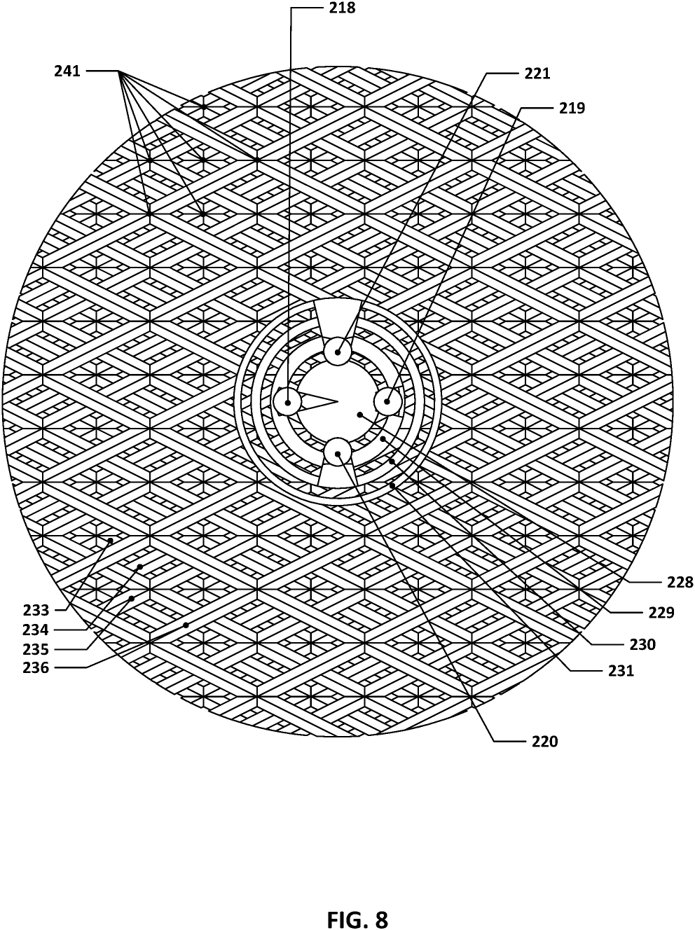

FIG. 8 depicts a top view of the flow paths within the example showerhead of FIG. 2. As can be seen, the transverse passages 233 through 236 form a series of offset rhombic lattice pattern shapes. A gas distribution port may be located beneath each intersection point 241 between two transverse gas passages 233 through 236.

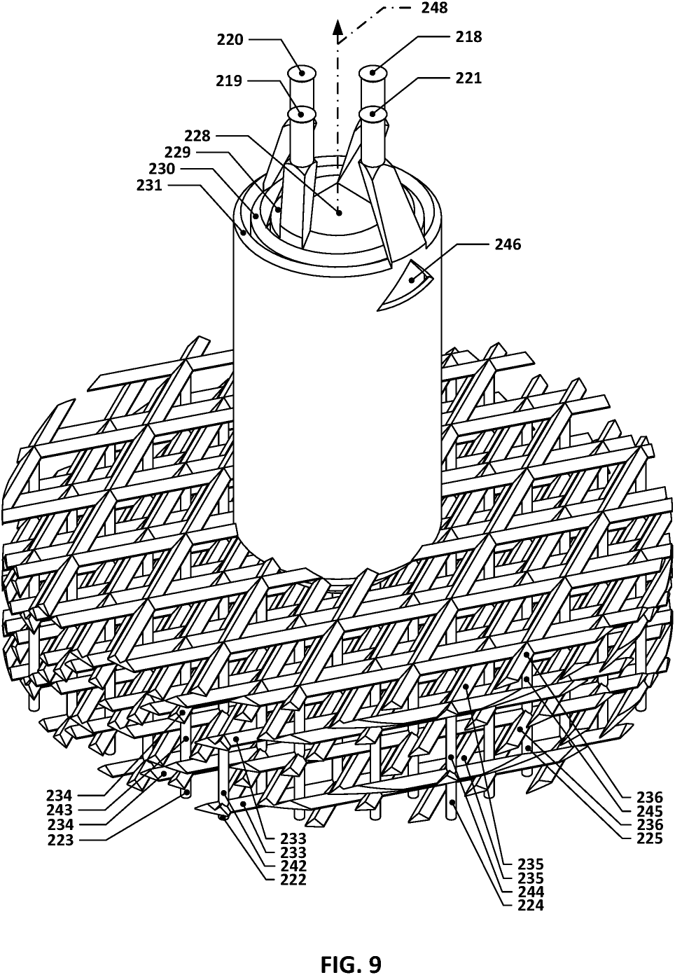

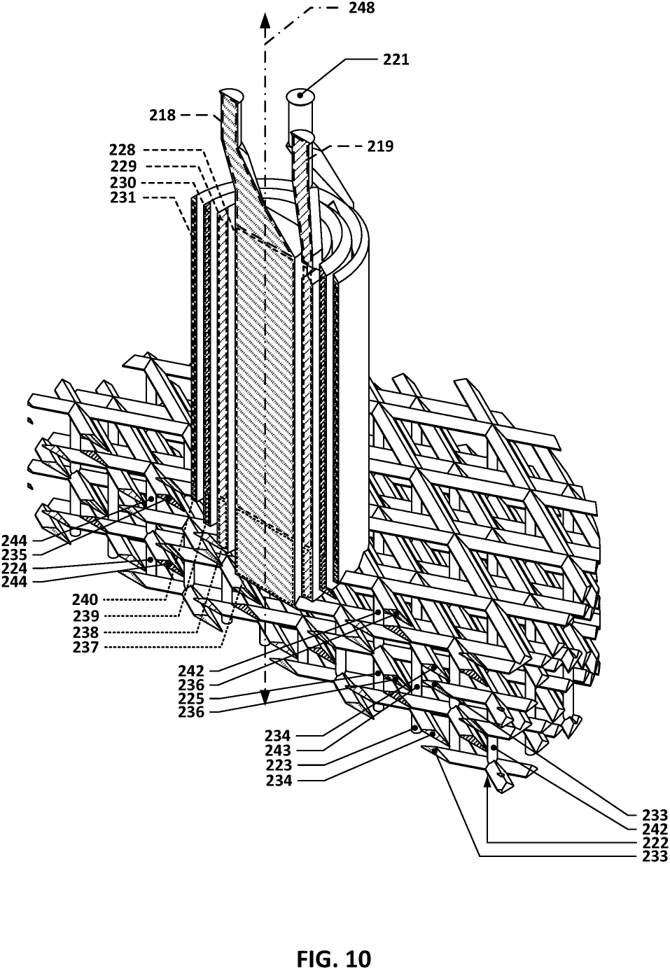

The complex arrangement of transverse passages shown in FIG. 8 is more evident in FIGS. 9 and 10, which depict perspective and perspective section views of the flow paths within the example showerhead of FIG. 2. The concentric annular nature of the first through fourth fluidic inlet passages 228 through 231 is more evident in these views.

Also visible in FIGS. 9 and 10 is a portion of the fourth fluidic inlet passage 231 that corresponds to the location of a flow divider structure 246. The flow divider structure 246 may, for example, be a triangular- or lachrymiform-shaped feature that is located within the fourth fluidic inlet passage 231 and positioned below the fourth fluidic inlet port 221 so that fluid, e.g., gas, that is flowed out of the fourth fluidic inlet port 221 and into the fourth fluidic inlet passage 231 is caused to both change directions (to a slanted direction having both axial and circumferential components as opposed to purely axial flow) and split into two separate flows, thereby causing such fluid to more evenly disperse within the fourth fluidic inlet passage 231. A lachrymiform-shaped feature is, for example, a feature having a tear-drop shape; in such instances, the rounded portion of the tear may be facing towards the bottom, with the pointed end of the tear pointed towards the fourth fluidic inlet port 221. While not visible in FIG. 9, similar flow divider structures may also be included in one or more of the other fluidic inlet passages 228-230. In FIG. 9, what appears to be a triangular cutout in the fourth fluidic inlet passage 231 is representative of the triangular-shaped flow divider structure that would extend between the walls of the stem portion 203 that bound the fourth fluidic inlet passage 231 and occupy the triangular-shaped cutout area.

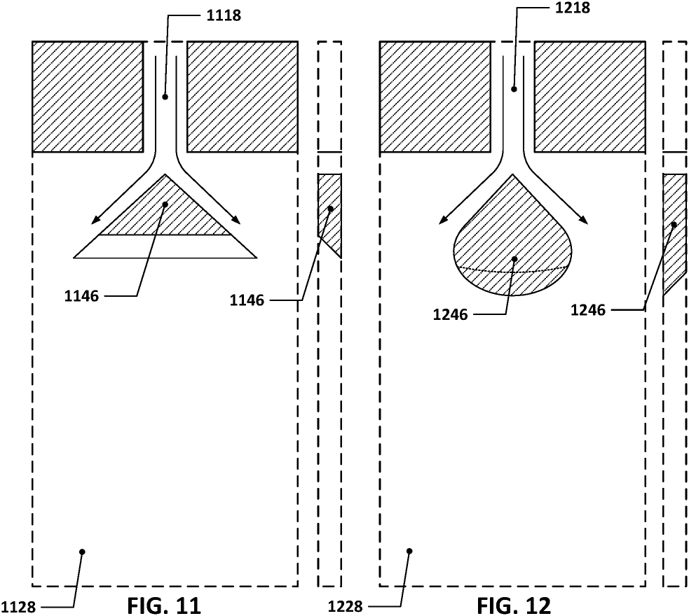

FIGS. 11 and 12 depict simplified schematic views of two flow divider arrangements; both Figures show a portion of a fluidic inlet port and an annular inlet passage that has been “unrolled” flat in the left side of each Figure. Each Figure also shows, at right, a radial cross-sectional view of such structures. In FIG. 11, a first fluidic inlet port 1118 provides gas flow into a first fluidic inlet passage 1128. A flow divider structure 1146 (a triangular cross-section one, in this example), is positioned within the first fluidic inlet passage 1128 such that a plane that would be coplanar with the stem center axis (not shown, but see other Figures) passes through both the first fluidic inlet port 1118 and the flow divider structure 1146. Alternatively, the flow divider structure 1146 may be described as being positioned below the first fluidic inlet port 1118 such that fluids, e.g., gases, flowing out of the first fluidic inlet port 1118 may be divided into two flows that are diverted in directions having an increased directional component to the left and right of the flow divider structure 1146. As can be seen in the cross-sectional view at right in FIG. 11, the flow divider structure 1146 may have a sloped bottom surface, e.g., a surface that is, for example, at 45° or more from horizontal. This may, as discussed later herein with respect to the transverse passage cross-sectional geometries, provide for more reliably manufacturable flow divider structures as compared with similar flow divider structures with horizontal bottom surfaces. FIG. 12 shows a similar arrangement with a first fluidic inlet port 1218 that provide gases to a first fluidic inlet passage 1228, but instead of a triangular flow divider structure 1146, a lachrymiform-shaped flow divider structure 1246 is used. The bottom surface of the flow divider structure 1246 may be similarly sloped, as is evident in the cross-sectional view at right in FIG. 12 (despite not having a flat bottom surface, it may still be desirable to design the bottom surface of the flow divider structure 1246 so that it has, at any given point, a tangent surface that is sloped at greater than or equal to 45° from horizontal.

In some implementations, such as that discussed above, each flow path through the showerhead may include multiple sets of transverse passages. In such implementations, each set of transverse passages may be fluidically connected with another set or sets of transverse passages by corresponding riser passages. For example, the first flow path through the showerhead body 202 features two sets of first transverse passages 233 at different elevations; the lower set of first transverse passages 233 is fluidically connected with the upper set of first transverse passages 233 by first riser passages 242, which may extend vertically from, and fluidically connect, the lower set of first transverse passages 233 to the upper set of first transverse passages 233. The lower set of first transverse passages 233 may be fluidically connected with the first gas distribution ports 222.

Similarly, there may be an upper set of second transverse passages 234 that are fluidically connected with a lower set of second transverse passages 234 by second riser passages 243, an upper set of third transverse passages 235 that are fluidically connected with a lower set of third transverse passages 235 by third riser passages 244, and an upper set of fourth transverse passages 236 that are fluidically connected with a lower set of fourth transverse passages 236 by fourth riser passages 245. The lower sets of second transverse passages 234, third transverse passages 235, and fourth transverse passages 236 may also each respectively be fluidically connected with the second gas distribution ports 223, third gas distribution ports 224, and the fourth gas distribution ports 225. In implementations in which more than two sets of transverse passages are used for each flow path, additional sets of riser passages may be fluidically interposed between each additional set of transverse passages and the closes adjacent set of transverse passages for that flow path.

It will be understood that, generally speaking, each set of transverse passages may be fluidically interposed between two other fluid flow features (or sets thereof). For example, each upper set of transverse passages may be fluidically interposed between a corresponding set of riser passages and one or more corresponding fluidic inlets. Similarly, each lower set of transverse passages may be fluidically interposed between a corresponding set of riser passages and a corresponding set of gas distribution ports. Similarly, each set of riser passages may be fluidically interposed between two sets of transverse passages.

It will also be appreciated that while the depicted example features riser passages that are co-axial with the corresponding gas distribution ports for the relevant flow path, e.g., generally centered on the locations where transverse passages intersect, other implementations may see the riser passages positioned differently, e.g., at positions midway between transverse passage intersections and/or with a different spacing, e.g., every other intersection or midway between every other pair of transverse passage intersections. Similarly, the gas distribution ports that are located at each intersection point between transverse passages may alternatively be positioned at other locations, e.g., shifted from such locations such that each gas distribution port is midway between two such intersection points (or at a location spaced apart from the closest intersection point by such a distance—e.g., for gas distribution ports at the periphery of the lattice pattern, there may not be another intersection point “outside” of the gas distribution port).It will be further appreciated that there may be portions of the showerhead body 202 in which riser passages may be omitted. For example, if there is no corresponding transverse passage positioned above a portion of another transverse passage for the same flow path, no riser passage would be provided at that location. For example, the upper set of fourth transverse passages 236 in FIGS. 9 and 10 terminate at the outer boundary of the fourth fluidic inlet 240. Thus, no fourth riser passages 245 would be provided at locations within the inner boundary of the fourth fluidic inlet 240 (when viewed along center axis 248) as there are no upper fourth transverse passages 236 provided at those locations for such risers to connect to. Similar adjustments may be made for other sets of transverse passages as well.

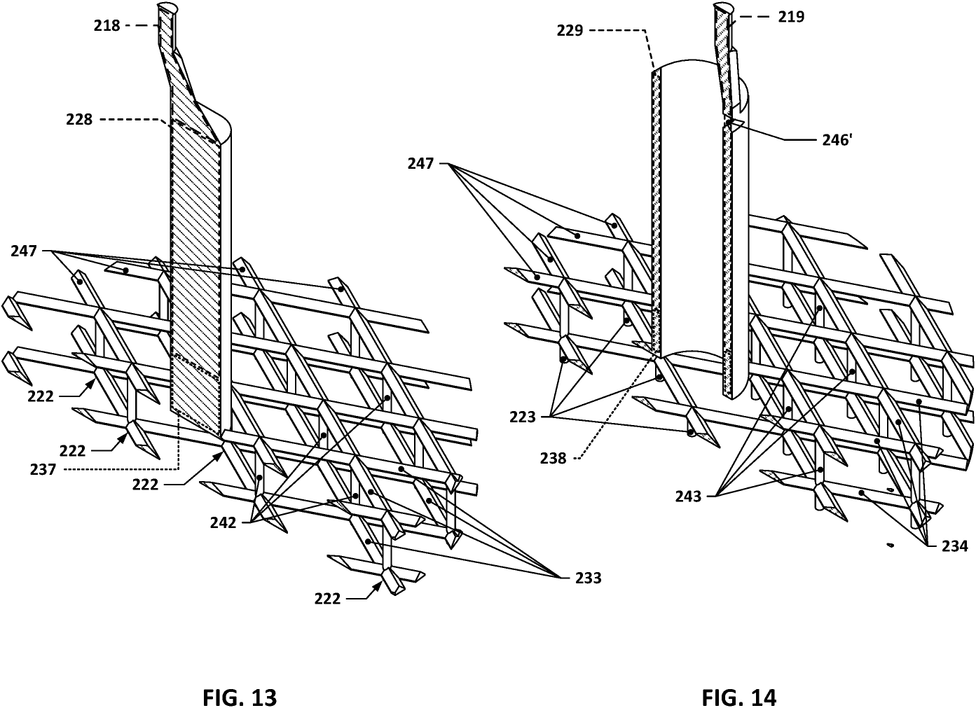

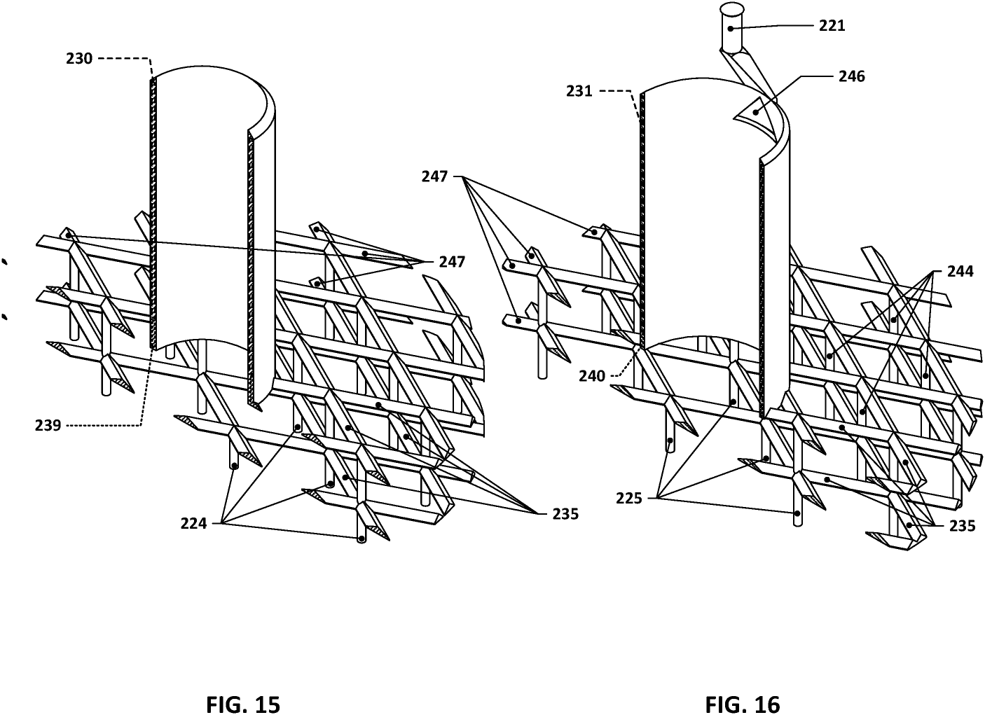

FIGS. 13 through 16 depict perspective section views of first, second, third, and fourth flow paths, respectively, of the flow paths within the example showerhead of FIG. 2. As seen in FIGS. 13 through 16, each flow path generally features a similar pattern of repeating transverse passages arranged in a rhombic lattice arrangement. In the depicted examples, each riser passage generally lines up with a corresponding gas distribution port, which may allow, for example, for more precise control of the riser passage and distribution port feature sizes/tolerances. For example, while additive manufacturing techniques are continually being refined and improved, it is often very difficult to create additively manufactured parts with smooth surfaces due to aliasing effects inherent in most or all additive manufacturing techniques due to the use of XY stepper motors to drive the additive manufacturing system print head as well as the layer-by-layer approach used to “build up” an additively manufactured part. As a result, it may be desirable to perform post-additive-manufacturing subtractive machining operations on an additively manufactured showerhead to ensure that features such as the gas distribution ports, and potentially the riser passages, have uniform and consistent cross-sectional shapes. For example, it may be desirable to drill out the gas distribution ports (and possibly the riser passages) with a drill, thus ensuring a truly round (and consistently dimensioned) cross-section for those features, as well as providing a consistent surface finish. Such drilling operations may, however, be relatively rapidly achieved since the additively manufactured gas distribution ports (and possibly riser passages) act as full-depth rough-drilled holes that guide the finishing drilling operation and which already result in most of the material to be removed being absent—the finishing drilling operation may thus act most like a honing operation by simply removing a few thousands of an inch of material, for example, from a given gas distribution port (and optional riser passage). Of course, it may also be unnecessary to perform such post-additive-manufacturing finishing operations if the quality of the additively manufactured component is sufficiently high enough that such operations may be omitted.

In the example showerhead discussed above, the transverse passages were all designed to be chords of a common outer boundary circle (as can be seen in FIG. 8, the ends of the transverse passages form a perfect circle, so the ends of each transverse passage lie exactly on that circle). As a result, the transverse passages of this example showerhead often have dead legs 247, i.e., portions thereof that are a fluidic dead-end in that fluid that flows into such a portion has no way of exiting that portion except by flowing back out through the aperture through it entered that portion. Such dead legs are often undesirable in semiconductor gas systems since it is often the case that such systems may need to flow different, mutually reactive gases through a common flow path; in order to prevent undesired reactions between such gases within those flow paths (which may damage the flow paths or generally undesirable particulates), such systems typically purge the flow path between the flow of each reactant. This takes time and also tends to waste the gas that is purged out of the flow path. In particular, if there are dead legs present in such a system, it becomes very difficult, and potentially impossible, to fully purge such a system since process gases may become trapped in the dead legs 247. Purge gas is unable to flow into the dead legs due to the lack of an exit path, and so the process gas that has entered the dead legs tends to remain (over time, there will be diffusion of gases into/out of the dead legs, but it would take typically much more time than is generally permissible during a semiconductor processing operation for such diffusion of purge gas to adequately purge the process gas from the dead legs).

In a multi-flow path showerhead such as that discussed above, the showerhead may include a larger number of flow paths in a given volume (the showerhead body) than may usually be feasible in other showerheads having the same volume available for flow paths. As a result, such showerheads may avoid the need to re-use flow paths for different gases, and thereby avoid the need to purge such flow paths. In view of this, the presence of dead legs 247 in showerheads such as those discussed herein may not offer the same negative effects as would normally result from the presence of such dead legs in a showerhead which re-used flow paths for different gases. Moreover, there may actually be an advantage to including such dead legs 247 in a showerhead such as the example discussed above—the material that would normally be used to “fill” such dead legs may simply be directly recycled in the additive manufacturing system, e.g., re-used in later additive manufacturing operations of other components. In other words, the increased void space within the showerhead that arises from the inclusion of such dead legs means that the showerhead body 202 requires less material in order to be manufactured. Since the “waste” material from selective laser melting or similar processes can simply be re-used in a subsequent additive manufacturing run, the materials savings arising from dead leg inclusion can actually make such showerheads cheaper. An additional cost savings may be realized through the use of such dead-legs since the time normally spent “filling in” the dead legs may be avoided, thereby reducing manufacturing time.

Multi-path showerheads with dead legs in them may, in some cases, still be undesirable, however. For example, the surface finish that may result from additive manufacturing may be too rough, in some circumstances, to develop a desired fluid flow profile, or there may be powder granules that are not fully melted but are only lightly attached or fused to the surrounding structure and may come off during use, thereby contaminating a wafer being processed using such a showerhead. As noted earlier, post-additive-manufacturing subtractive machining operations, such as drilling operations performed on the gas distribution ports (and possible riser passages) may help provide a more uniform surface finish in those regions of the showerhead, but this may also be a concern within the transverse passages of the showerhead (or in any other part of the showerhead that cannot be easily reached by a machine or tool head capable of smoothing that surface finish. In such cases, other types of smoothing or polishing operations may be performed, e.g., electropolishing, slurry polishing, etc., that are liquid-based, thereby allowing the liquid-entrained or liquid-provided polishing agent to be flowed into the showerhead and used to polish the interior surfaces thereof. In some such cases, however, it may be difficult for the polishing agent to polish the surfaces of the dead legs due to the generally stagnant flow conditions within the dead legs. In such circumstances, it may be desirable to avoid the use of dead legs within a showerhead, even if it results in an increased manufacturing part cost due to increased material usage.

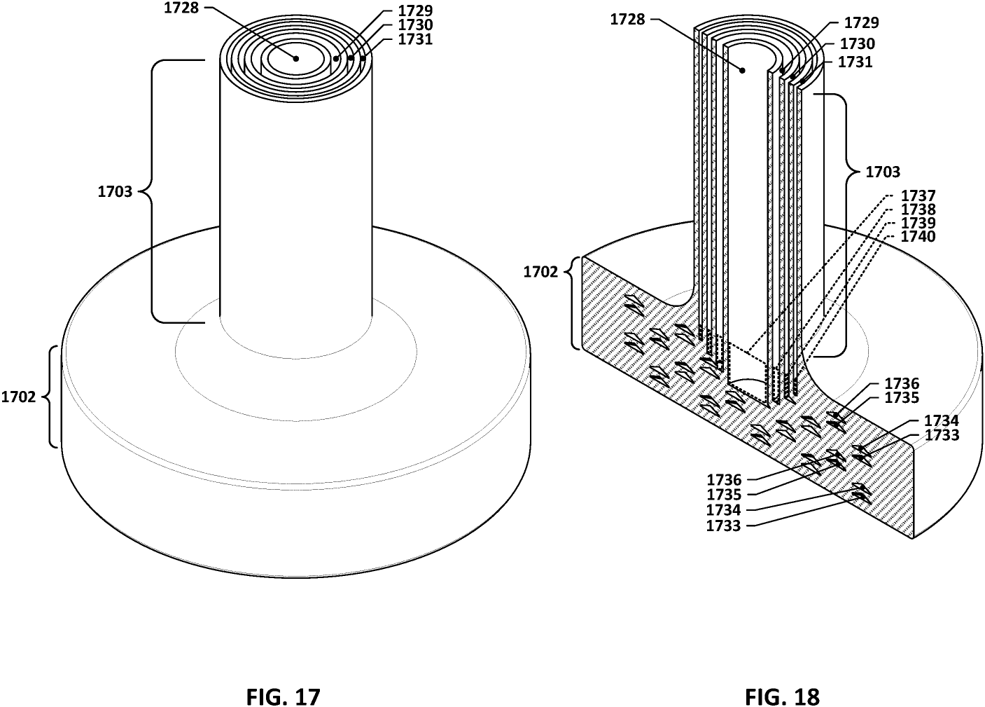

FIG. 17 depicts a perspective view of another example showerhead having various features disclosed herein; this example showerhead omits the upper portion of the stem portion (including the fluidic inlet ports) for simplicity (it may be assumed to have similar such features as in the previous example provided), but also omits entire the use of dead legs. The showerhead 1701 shown in FIG. 17 includes a stem portion 1703 connected to a showerhead body 1702. Visible in the stem portion 1703 are a first fluidic inlet passage 1728, a second fluidic inlet passage 1729, a third fluidic inlet passage 1730, and a fourth fluidic inlet passage 1731.

FIG. 18 depicts a perspective section view of the example showerhead of FIG. 17. As can be seen, the cross-section is very similar to that shown in FIG. 7, except small portions of dead legs 247 can be seen at the outer perimeter of the showerhead body 202 in FIG. 7 that are not visible in the showerhead body 1702. In addition to the features discussed above with respect to FIG. 17, portions of first transverse passages 1733, second transverse passages 1734, third transverse passages 1735, and fourth transverse passages 1736 can be seen. As with the showerhead 201, there are two sets each, a lower set and an upper set, of the first transverse passages 1733, second transverse passages 1734, third transverse passages 1735, and fourth transverse passages 1736.

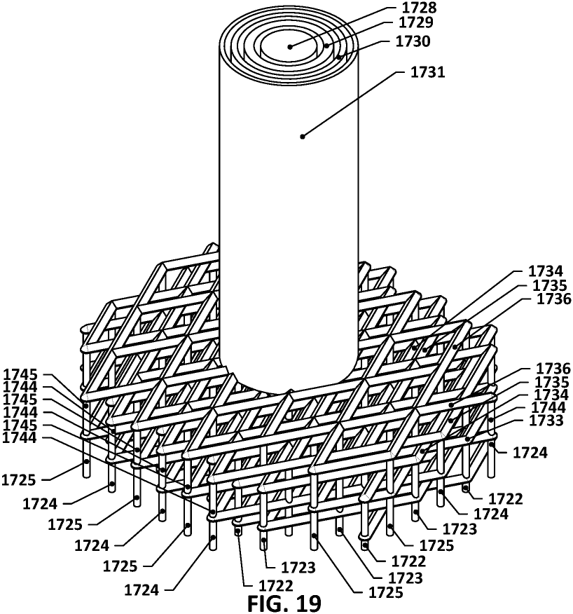

FIG. 19 depicts a perspective view of the flow paths within the example showerhead of FIG. 18. As can be seen, each flow path includes transverse passages that do not extend beyond (or only extend minimally beyond, e.g., by one half of the difference between the width of the transverse passage and the diameter of the gas distribution ports and/or the riser passages) the outermost gas distribution ports and/or riser passages of the showerhead body 1702. Thus, the first flow path may include the first fluidic inlet passage 1728, which may flow gas to the upper set of the first transverse passages 1733, which may, in turn, flow that gas to first riser passages 1742 and, from there, through the lower set of the first transverse passages 1733 and into first gas distribution ports 1722. Similarly, the second flow path may include the second fluidic inlet passage 1729, which may flow gas to the upper set of the second transverse passages 1734, which may, in turn, flow that gas to second riser passages 1743 and, from there, through the lower set of the second transverse passages 1734 and into second gas distribution ports 1723. The third flow path may include the third fluidic inlet passage 1730, which may flow gas to the upper set of the third transverse passages 1735, which may, in turn, flow that gas to third riser passages 1744 and, from there, through the lower set of the third transverse passages 1735 and into third gas distribution ports 1724. Similarly, the fourth flow path may include the fourth fluidic inlet passage 1731, which may flow gas to the upper set of the fourth transverse passages 1736, which may, in turn, flow that gas to fourth riser passages 1745 and, from there, through the lower set of the fourth transverse passages 1736 and into fourth gas distribution ports 1725.

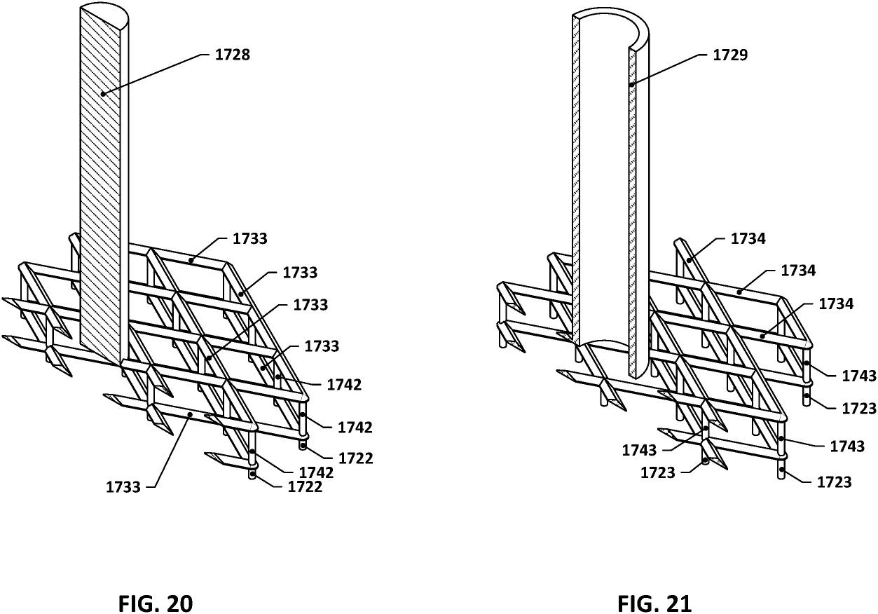

FIGS. 20 through 23 depict perspective section views of first, second, third, and fourth flow paths, respectively, of the flow paths within the example showerhead of FIG. 18.

For example, FIG. 20 depicts a perspective view of the first flow path, which includes the upper and lower sets of first transverse passages 1733. Also visible are the first riser passages 1742 and the first gas distribution ports 1722 (in the example showerhead 201, the first gas distribution ports 222 were somewhat obscured in most views by the dead legs of the first transverse passages 1733). As can be seen, the first transverse passages 1733 are arranged in a non-orthogonal rhombic lattice, and the first gas distribution ports 1722 are arranged in a non-orthogonal rhombic lattice pattern, similar to that of the showerhead 201.

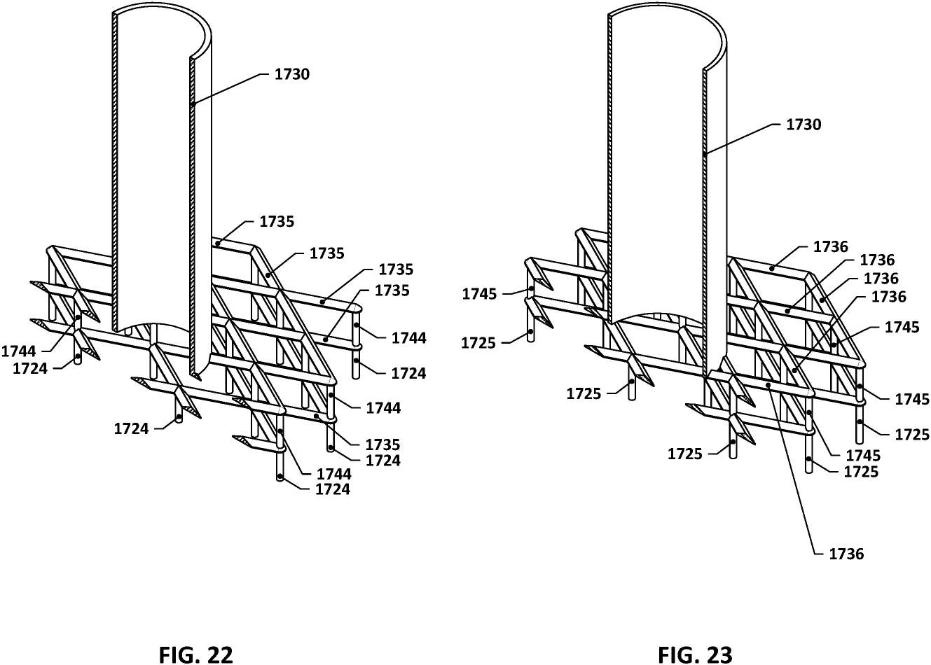

Similarly, FIG. 21 depicts a perspective view of the second flow path, which includes the upper and lower sets of second transverse passages 1734. Also visible are the second riser passages 1743 and the second gas distribution ports 1723. FIG. 22, likewise, depicts a perspective view of the third flow path, which includes the upper and lower sets of third transverse passages 1735. Also visible are the third riser passages 1744 and the third gas distribution ports 1724. Finally, FIG. 23 depicts a perspective view of the fourth flow path, which includes the upper and lower sets of fourth transverse passages 1736 and the fourth riser passages 1745 and the fourth gas distribution ports 1725.

In the above example, there are two rhombic lattice patterns of transverse passages for each flow path which are arranged such that the riser passages that connect the transverse passages of each rhombic lattice pattern are directly over corresponding gas distribution ports that flow gas from the lower transverse passages out of the showerhead. However, it will be appreciated that other arrangements of transverse passages and/or gas distribution ports and/or riser passages may be practiced as well.

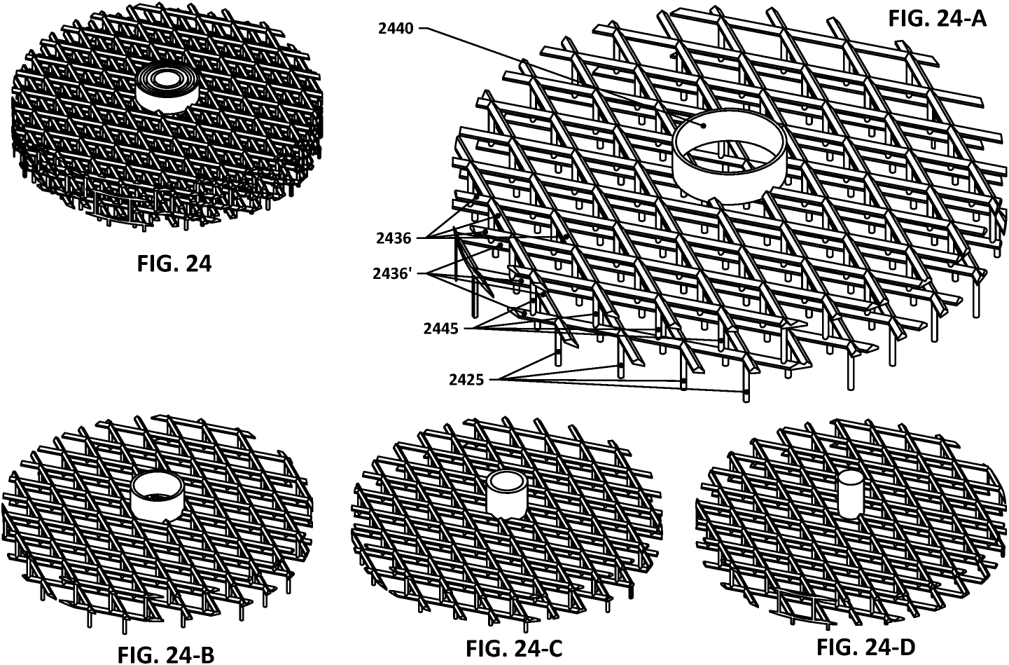

FIG. 24 depicts an isometric view of a plurality of flow paths for an example showerhead. The flow paths shown in FIG. 24 reflect those of a showerhead in which each flow path includes two rhombic lattice patterns of transverse passages, as with earlier showerheads discussed herein. However, the rhombic lattice patterns of the depicted flow paths in FIG. 24 are arranged somewhat differently. The most readily apparent difference is that the riser passages, as can be seen more clearly in FIGS. 24-A through 24-D, that span between each rhombic lattice pattern of transverse passages fluidically connect with the upper rhombic lattice pattern of transverse passages at locations that coincide with the intersection of two transverse passages but connect with the lower rhombic lattice pattern of transverse passages at locations in between adjacent intersections of transverse passages, e.g., near the middle of each transverse passage segment that lies between two adjacent transverse passages that are at an angle to the segment. Such an arrangement may provide for more event gas distribution, as the gas that flows through the riser passages is forced to flow horizontally again before flowing out of the gas distribution passages.

For example, in FIG. 24-A, a fourth fluidic inlet 2440 may provide gas to a set of fourth transverse passages 2436 that feed the gas through fourth riser passages 2445 to a set of fourth transverse passages 2436′. The gas may then turn 90° and flow along the lower set of fourth transverse passages 2436′ before flowing out of fourth gas distribution ports 2425. The other flow paths, as illustrated in FIGS. 24-B through 24-D, may be constructed similarly.

The other difference between the showerhead flow paths shown in FIG. 24 and those discussed earlier is that the rhombic lattice patterns of transverse passages in FIG. 24 are not evenly spaced from each other. For example, some earlier examples, if there were four flow paths, each having a rhombic lattice pattern with a maximum pitch of 30 units and arranged such that the long axes of the rhombuses in the patterns were aligned, then each rhombic lattice pattern may be shifted along the long axes of the rhombuses in the patterns by an amount equal to the maximum pitch divided by the number of rhombic lattice patterns. However, in the depicted example of FIG. 24, the rhombic lattice patterns for each flow path are shifted relative to each other along the long axes of the rhombuses in the patterns by an even multiple of an amount equal to the maximum pitch divided by one more than the number N of rhombic lattice patterns. In effect, thus results in N rhombic lattice patterns being located at locations along an axis that are spaced apart as if N+1 rhombic lattice patterns were spaced apart equal distances within the same distance (the maximum pitch). For example, if the maximum pitch is 30 units and there are four flow paths, each with a corresponding lattice pattern, the lattice patterns would be offset from one another along their long axes by a distance that is a multiple of 5 units. However, since the spacing between rhombic lattice patterns is based on the assumption of there being one more rhombic lattice pattern than there actually is, this results in there being a gap or void in the equally spaced rhombic lattice patterns, e.g., as if there had been an extra rhombic lattice pattern that was then removed, leaving a vacancy in the set of rhombic lattice patterns.

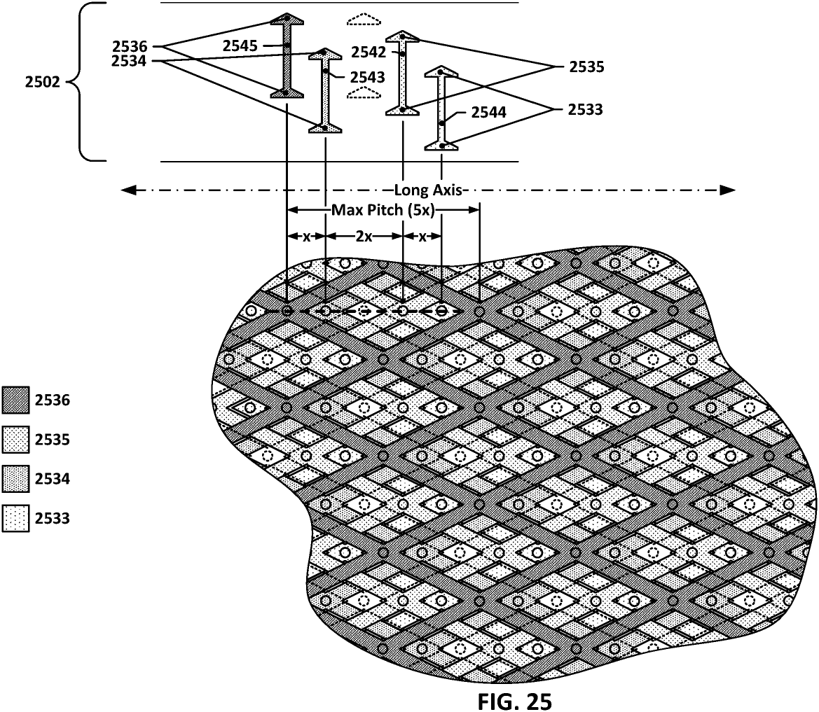

FIG. 25 provides a more detailed overview of this. In FIG. 25, a set of four rhombic lattice patterns of transverse passages 2533 through 2536 is shown (the outer boundaries of the rhombic lattice patterns are arbitrarily defined, as this is a detail view of an example set of rhombic lattice patterns. The rhombic lattice patterns have a long axis that is parallel to the indicated long axis. The maximum pitch of the lattice patterns (which is the same for all of the rhombic lattice patterns) is indicated as shown. The spacing/offset along the long axis between, for example, the lattice pattern for the fourth transverse passages 2536 and the lattice pattern for the second transverse passages 2534 may, for example, be one fifth of the maximum pitch. Similarly, the spacing along the long axis between, for example, the lattice pattern for the first transverse passages 2533 and the lattice pattern for the third transverse passages 2535 may, for example, also be one fifth of the maximum pitch. However, the spacing along the long axis between, for example, the lattice pattern for the second transverse passages 2534 and the lattice pattern for the third transverse passages 2535 may, for example, be two fifths of the maximum pitch. This results in a gap in the lattice patterns that is large enough to fit a fifth lattice pattern (represented by dotted lines). Instead of providing a fifth lattice pattern, however, the lattice patterns for each flow set may instead be offset from one another along an axis aligned with one of the transverse passage directions such that the riser passages (represented by circles) extending downward from the transverse passage intersection points shown in FIG. 25 intersect the lower set of transverse passages at locations that are mid-span, close to mid-span, or at the very least not directly over the gas distribution ports for the respective flow paths. The gap permits such an offset between sets of transverse passages, e.g., between the top set of transverse passages and the bottom set of transverse passages (such as are shown in FIG. 24).

Also shown in FIG. 25 at the top are side view cross-sections of portions of the transverse passages in each set of transverse passages. The pentagonal cross sections are taken at an angle with respect to the centerlines of the transverse passages 2533-2536, and thus appear to have a larger “roof angle” than the 90° that is actually used along the top of each transverse passage 2533-2536 in this example. The cross-sections each include a riser passage 2542-2545 and both the upper transverse passage for each set and the lower transverse passage for each set (the lower transverse passages are not shown, however, in the detail plan view discussed above). The cross-sections, for example, are taken along the heavy dashed line directly below the cross-sections and in the larger portion of FIG. 25. As can be seen, the lattice patterns of transverse passages are not arranged in “descending” or “ascending” order within a showerhead body 2502, i.e., with the rhombic lattice patterns that are closest together along the long axis also being closest together in directions parallel to the axes along which the riser passages extend. Instead, the rhombic lattice patterns are arranged such that the rhombic lattice pattern for the second transverse passages is offset horizontally by three fifths of the maximum pitch from the rhombic lattice pattern for the first transverse passages, the rhombic lattice pattern for the fourth transverse passages is offset horizontally three fifths of the maximum pitch from the rhombic lattice pattern for the third transverse passages, and the rhombic lattice pattern for the second transverse passages is offset horizontally two fifths of the maximum pitch from the rhombic lattice pattern for the third transverse passages. Such an arrangement allows for the riser passages extending from the intersection points of the transverse passages in the upper rhombic lattice patterns to intersect the transverse passages in the lower rhombic lattice patterns at locations near the midpoint of each transverse passage segment, which may provide more uniform gas flow distribution. Other arrangements of rhombic lattice patterns may be used as well but may result in the point of intersection of the riser passages with the lower transverse passages moving closer to the intersections between transverse passages.

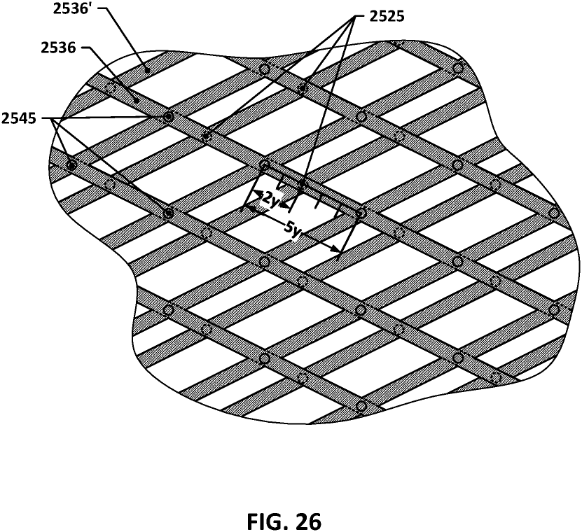

FIG. 26 provides a detail plan view of the transverse passages for a single flow path for the implementation of FIG. 25. As can be seen in FIG. 26, only the fourth transverse passages 2536 and 2536′ are shown—the other three sets of transverse passages evident in FIG. 25 are omitted. Moreover, both upper fourth transverse passages 2536 and lower fourth transverse passages 2536′ are shown, whereas in FIG. 25, only the upper fourth transverse passages 2536 (and other upper transverse passages) were shown. FIG. 26 demonstrates how the two rhombic lattice patterns used for each set of fourth transverse passages 2536 and 2536′ may be offset or staggered from one another, e.g., along one of the lattice directions. In this case, the offset is along an axis that passes through the centers of two adjacent fourth riser passages 2545 that are connected by a segment of a single fourth transverse passage 2536, and the amount of the offset is two fifths (2y) of the distance (5y) between adjacent fourth riser passages 2545 that are connected by a segment of a single fourth transverse passage 2536. Such an offset allows the fourth gas distribution ports 2525 to be similarly offset from the fourth riser passages 2545, thereby forcing the gas that is flowed through the flow path to travel horizontally (and thus be more evenly distributed) in order to reach a fourth gas distribution port 2525 from a fourth riser passage 2545. It will be recognized that a similar effect may be obtained as well without offsetting the rhombic lattice patterns of the transverse passages, but instead offsetting the locations of the gas distribution ports in a similar manner. For example, if the fourth gas distribution ports 2545 were to stay in the locations shown in FIG. 26 and the rhombic lattice pattern of the fourth transverse passages 2536′ were to be aligned with the rhombic lattice pattern of the fourth transverse passages 2536 (so that the upper fourth transverse passages 2536 would completely obscure the lower fourth transverse passages 2536′ in this view), this would result in the fourth gas distribution ports 2525 fluidically connecting with the lower fourth transverse passages 2536′ not at the intersection points between the lower fourth transverse passages 2536′, but instead near the middle of each segment of the lower fourth transverse passages 2536′, which would provide a similar effect. Similarly, the fourth riser passages 2545 may also be shifted in location relative to the fourth gas distribution ports 2525, e.g., such that the fourth riser passages instead connect with the fourth transverse passages 2536 and 2536′ at locations other than where the fourth transverse passages 2536 and 2536′ intersect within each rhombic lattice pattern.

The sets of transverse passages for the other flow paths may be similarly staggered for each such flow path. It will be understood that other offsets between upper and lower rhombic lattice patterns (or riser passages and/or gas distribution ports) may be used in other implementations, and that this is just one example of such an offset.

The above example is but one example in which the gas distribution ports for a given flow path may be located such that they are not directly below the riser passages for that flow path; other similar examples are considered to be within the scope of this disclosure as well.

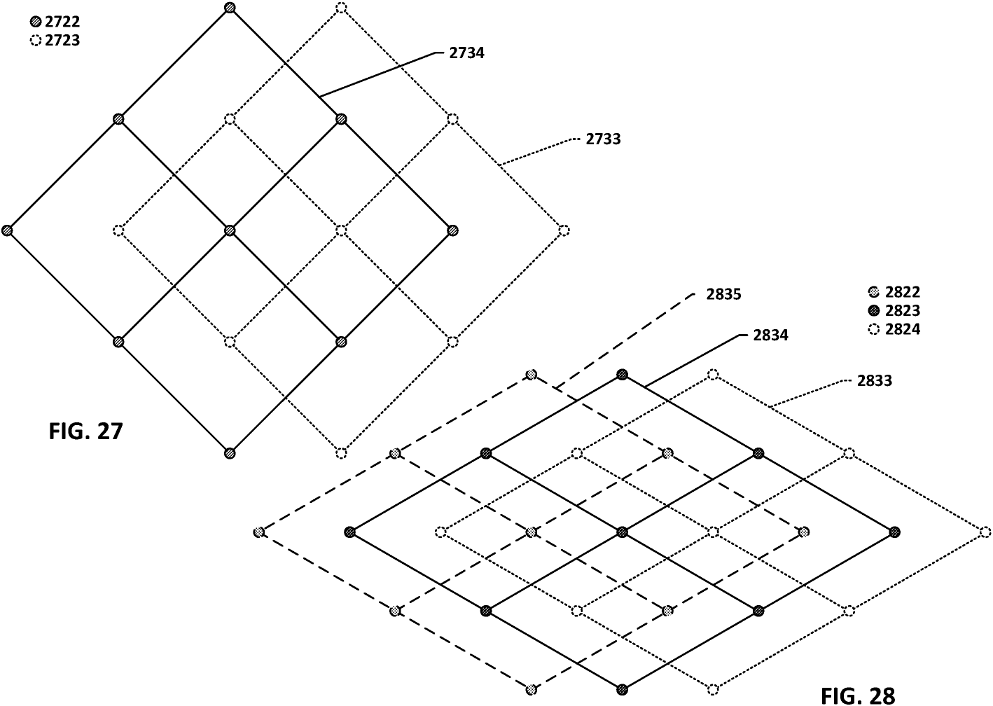

As mentioned earlier, the examples discussed above include four separate flow paths through the showerhead, but may include fewer or more such flow paths. FIG. 27 depicts an example of a rhombic lattice pattern that may be used for a dual-flow path showerhead. In FIG. 27, a set of first transverse passages 2733 may be arranged in a grid pattern and may supply gas to first gas distribution ports 2722. Similarly, a set of second transverse passages 2734 may be arranged in a similar grid pattern and may supply gas to second gas distribution ports 2723. The two grid patterns, in this example, are both orthogonal rhombic lattices, and the first and second gas distribution ports 2722, 2723 are arranged in an orthogonal rhombic lattice pattern.

FIG. 28 depicts an example of a rhombic lattice pattern that may be used for a triple-flow-path showerhead. In FIG. 28, a set of first transverse passages 2833 may be arranged in a non-orthogonal rhombic lattice and may supply gas to first gas distribution ports 2822. Similarly, a set of second transverse passages 2834 and a set of third transverse passages 2835 may be arranged in similar non-orthogonal lattice patterns and may respectively supply gas to second gas distribution ports 2823 and third gas distribution ports 2824. The three transverse passage patterns, in this example, are all non-orthogonal rhombic lattices, and the first, second, and third gas distribution ports 2822, 2823, and 2824 are arranged in a non-orthogonal rhombic lattice pattern.

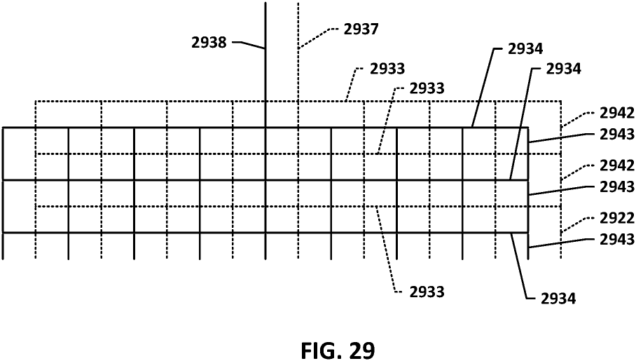

It will also be appreciated that more than two sets of transverse passages may be used in a given flow path. The use of one or more additional sets of transverse passages, e.g., three or more sets of transverse passages, may facilitate more even gas distribution and a more uniform gas delivery in some instances. FIG. 29 depicts an example side-view schematic of a flow path arrangement that features more than two sets of transverse passages per flow path. For example, in FIG. 29, a first fluidic inlet 2937 may provide process gases to an upper set of first transverse passages 2933, which may then flow from the upper set of first transverse passages 2933 through an upper set of first riser passages 2942 before flowing through a middle set of first transverse passages 2933 and then through a lower set of first riser passages 2942 before reaching a lower set of first transverse passages 2933 before flowing out of first gas distribution ports 2922. Similarly, a second fluidic inlet 2938 may provide process gases to an upper set of second transverse passages 2934, which may then flow from the upper set of second transverse passages 2934 through an upper set of second riser passages 2943 before flowing through a middle set of second transverse passages 2934 and then through a lower set of second riser passages 2943 before reaching a lower set of second transverse passages 2934 before flowing out of second gas distribution ports 2923.

In addition to the above parameters, of course, the number of gas distribution holes, transverse passages, and riser passages may be more or fewer than as depicted in the Figures discussed herein. For example, there may be thousands of gas distribution ports, e.g., on the order of 2000 to 3000 gas distribution ports in some showerheads (far more than the 120 gas distribution ports shown in FIG. 6, for example), as well as tens or hundreds of transverse passages . The gas distribution ports and transverse passages may also vary in size, e.g., the gas distribution ports may have having nominal cross-sectional sizes of between 0.25 mm to 2 mm in diameter. Moreover, due to the density with which the transverse passages, riser passages, and gas distribution ports may be printed, it may be possible to achieve very tight feature packing within a showerhead body. For example, in some implementations, sets of transverse passages may be separated from one another by as little as 0.5 mm of material.

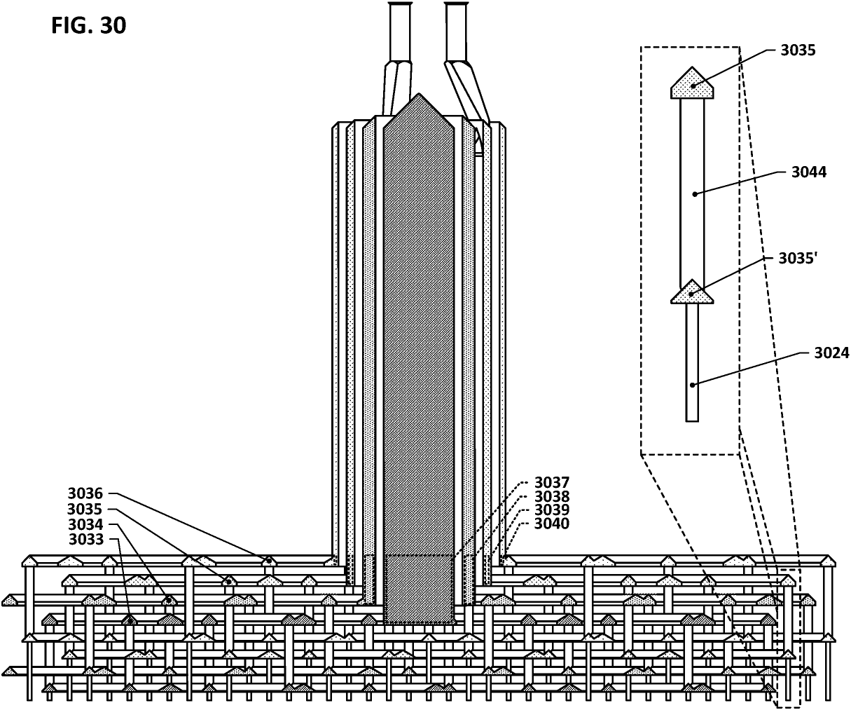

FIG. 30 depicts a cross-section of the flow paths for a showerhead similar to the examples discussed above. The flow paths include flow paths provided by first, second, third, and fourth transverse passages 3033, 3034, 3035, and 3036, respectively, as well as gas distribution ports, such as third gas distribution port 3024, and riser passages, such as third riser passage 3044. A detail view of one cross-section of one of the third transverse passages 3035 and 3035′ is shown at upper right in FIG. 30. As can be seen, in this implementation, the size (or diameter) of the third gas distribution port 3024 is reduced as compared with the size (or diameter) of the third riser passage 3044. The other riser passages and gas distribution ports may be similarly configured for the other flow paths. Such implementations may provide for a higher back pressure in the third transverse passages 3035′, thereby causing the gas that is flowed therethrough to be maintain a more uniform pressure before flowing out of the third gas distribution holes 3024 (thus resulting in more uniform gas flow/distribution out of the showerhead).

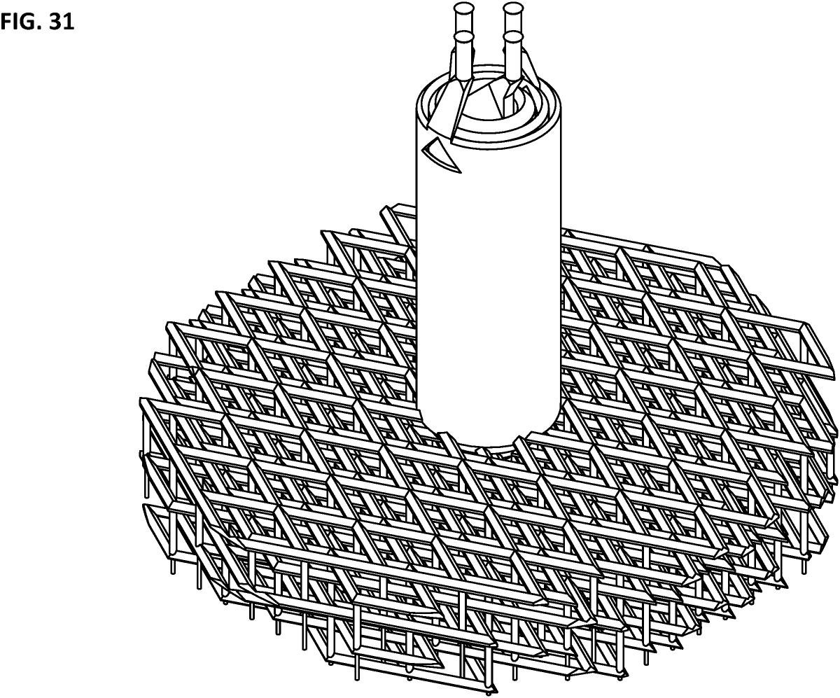

Also evident in FIG. 30 is that the third transverse passages 3035 have a larger cross-sectional area as compared with the third transverse passages 3035′. Such configurations may similarly result in higher back pressure within the third transverse passages 3035′ than in the third transverse passages 3035, thereby resulting in a more evenly distributed gas flow through the showerhead. The other transverse passages may be similarly configured. Thus, it will be appreciated that the cross-sectional area of the transverse passages may, in some implementations, be reduced in size for transverse passages for a given flow path that are closer to the exit plane of the showerhead than other transverse passages for that flow path that are further from the exit plane of the showerhead. Similarly, the gas distribution holes for a given flow path may be sized to be smaller in cross-sectional area than the riser passages for that flow path. FIG. 31 depicts an isometric view of the flow paths shown in FIG. 30.

In some implementations, such as those discussed above, the transverse passages may be arranged in an interleaved fashion when viewed along an axis perpendicular to the center axis of the stem portion. For example, each set of transverse passages (aside from the uppermost and lowermost such sets) may be interposed between sets of transverse passages for other flow paths. In some such examples, the sets of transverse passages may be arranged in an axially repeating pattern so that the riser passages for each flow path have the same lengths.

It will also be appreciated that while the above discussion has focused on transverse passages and gas distribution ports that are arranged to form rhombic lattice patterns and, in most cases, non-orthogonal rhombic lattice patterns, the concepts discussed herein may also be applicable in the context of parallelogram lattice patterns, which may include non-square rectangular lattice patterns and non-rhombic, non-orthogonal parallelogram lattice patterns. Such additional arrangements are considered within the scope of this disclosure as well.

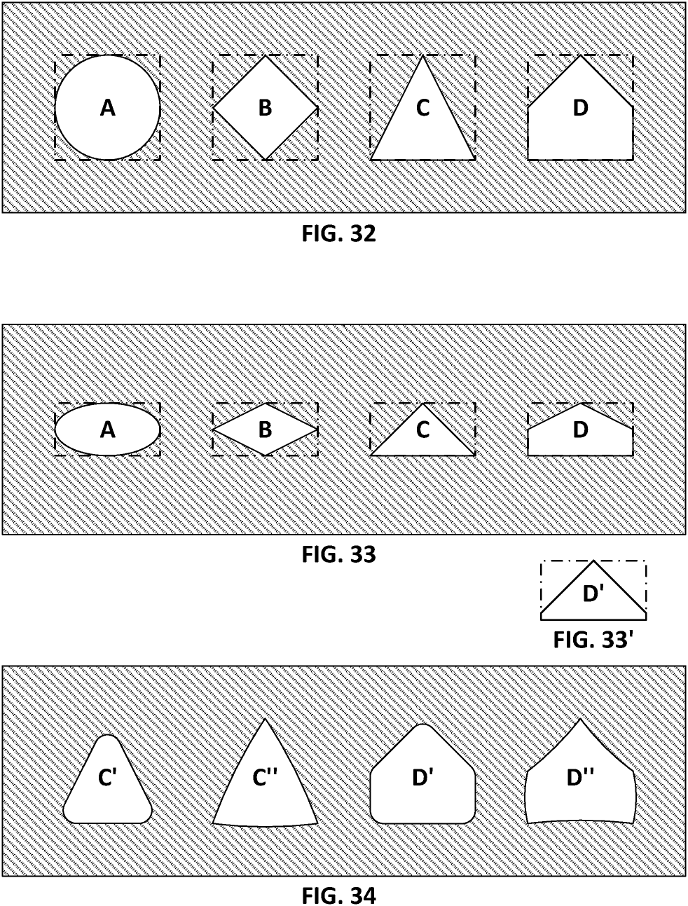

As noted earlier, the cross-sections that are used for the transverse passages may, in some instances (such as those shown in the examples discussed above) utilize particular cross-sectional shapes that are both manufacturable using additive manufacturing techniques such as selective laser melting and make efficient use of available volumetric space within the showerhead. FIG. 32 depicts four example cross-sections that were considered for use in additively manufactured showerheads. In FIG. 32, the cross-sectional shapes are shown relative to a 1×1 square frame (the dash-dot-dash squares), which may represent a nominal area available for use for accommodating a transverse passage. If it is desired to maximize flow conductance within a transverse passage that is to have a cross-section that fits within the square reference area, a transverse passage with the same cross-sectional shape as the square would, of course, provide such a maximum amount of flow conductance. The horizontal upper surface of such a transverse passage, however, would be ill-suited for being made using additive manufacturing techniques since it would, as discussed earlier, suffer from sagging or other defects that would compromise the surface finish and structural integrity of the upper surface. Thus, while a square passage would make the most efficient use of a square cross-sectional area, a transverse passage having such a cross-sectional shape would likely be ill-suited for use in an additive manufacturing context due to the above-mentioned defects.

A circular cross-section, such as that shown in cross-section A, would provide a relatively high usage of the available cross-sectional area within the square perimeter, occupying ~79% of it. However, due to the curvature of the circular profile along the upper edge (which becomes more and more unsupported from below as one approaches top dead-center), the circular cross-section would encounter similar problems to those encountered with the square cross-section during additive manufacturing, although to a somewhat smaller extent.

To avoid potential structural and surface finish issues, a diamond-shaped cross-section such as cross-section B may be used. Generally speaking, overhangs that are at an angle of 45° or more from horizontal are generally able to be made without significant structural or surface finish issues using additive manufacturing. Accordingly, a diamond-shaped cross-sectional shape that is bounded within a square region (and would thus have wall surfaces that were all at 45° relative to the horizontal plane) would be manufacturable using additive manufacturing without encountering any of the issues that would plague a circular or square-shaped cross section (it will be understood that a “square” cross-section, as the term is used herein, refers to a square cross-section having horizontal and vertical edges, while a “diamond” cross-section refers to a cross-section having bottom edges at equal and opposite angles relative to the horizontal, and top edges parallel to the bottom edges). However, the diamond-shaped cross-section would only utilize 50% of the available area within the square boundary.

Cross-section C, which is triangular, would be even more manufacturable using additive manufacturing techniques such as selective laser melting since the two upper walls would be at an even steeper angle than 45° to the horizontal. However, the cross-section C would, like the cross-section B, only utilize 50% of the available cross-sectional area.

In contrast, cross-section D, which is a pentagonal shape (or, more accurately, an isosceles pentagon or, even more accurately, a right isosceles pentagon), comes close to the performance of the circular cross-sectional shape A in terms of the percentage of the square area that it uses (75% compared to 79%), but suffers from none of the additive manufacturing issues that the circular cross-section does as long as the two upper surfaces of the pentagon are kept at angles of 45° or more from horizontal. Accordingly, if it desired to generally maximize the cross-sectional area of a transverse passage for the purposes of increasing flow conductance thereof, using a pentagonal cross-sectional shape (of the shapes discussed above) may generally provide the best performance.

FIG. 33 depicts similar cross-sectional shapes as in FIG. 32, but in the context of a reduced-height frame, e.g., a rectangular area that is 1 × 0.5 units in size.

The circular region A from FIG. 32 is now an elliptical area in FIG. 33 and will suffer even more severe issues with regard to structural integrity and surface finish along the uppermost portion thereof during additive manufacturing. Similarly, the diamond cross-section B of FIG. 32 is now squashed and has upper surfaces that are at angles of significantly less than 45° from horizontal and would therefore also be vulnerable to defects in the upper surfaces thereof during additive manufacturing processes. The triangular cross-section C, however, is still able to maintain upper surfaces that are at 45° or more relative to the horizontal and is thus still reliably manufacturable using additive manufacturing techniques. The pentagonal cross-section D, however, now has upper surfaces that are at less than 45° relative to the horizontal and thus cannot be reliably made using additive manufacturing techniques. Of course, the two vertical sides of the pentagonal cross-section D could be reduced in height to allow the angles of the upper surfaces to be increased, e.g., to at least 45°, relative to the horizontal, but with the 1 × 0.5 rectangular area used in FIG. 33, this practice causes the two vertical sides of the pentagonal cross-section to converge to zero-length sides, thus turning the pentagonal cross-section into the triangular cross-section C. Accordingly, while pentagonal cross-section transverse passages may, in the context of additively manufactured showerheads (or any other fluid-transporting device that is additively manufactured and is subject to the limitations on overhanging feature angles discussed earlier), offer high flow conductance (and potentially the highest flow conductance) within a rectangular cross-sectional region while still providing feature geometries that are amenable to being produced using such additive manufacturing techniques, triangular-cross-section transverse passages may the same advantages for the special case in which the transverse passage cross-section lies within a rectangular area that is twice as wide as it is tall. In the examples of FIGS. 2 and 17, the cross-sections of the transverse passages are generally as shown in FIG. 33′ for pentagon D′. As can be seen, the pentagon cross-section used in those example implementations features very short vertical sides and is almost triangular in shape; the rectangular region in which the pentagon cross-section fits is approximately 0.55:1 in size, so not quite the 0.5:1 ratio of the rectangular regions of FIG. 33.

It will also be appreciated that in some implementations having transverse passages that have triangular or pentagonal cross sections, those cross-sections may only be nominally triangular or pentagonal. For example, FIG. 34 depicts example triangular cross-sections C′ and C″ that feature rounded corners (C′) or somewhat curved sides (C″), as well as example pentagonal cross-sections D′ and D″ that feature rounded corners (D′) or somewhat curved sides (D″). Such shapes are still considered to be nominally triangular or pentagonal in shape, and a person would understand such shapes to generally be triangular or pentagonal if referenced as being such. It will be further understood that if terms such as “nominally” are required to be removed from such phrases in the claims in spite of the clarity provided above, such removal is not intended to be a surrender of claim scope and the amended phrases should be viewed as being inclusive of both the exact shape recited as well as other shapes consistent with the guidance provided above.

In the discussion above and the examples provided in the Figures, the transverse passages have been depicted as extending along horizontal directions, e.g., generally perpendicular to the center axis of the stem portion, and the gas distribution ports, riser passages, and other fluidic flow passages have been depicted as extending along vertical directions, e.g., generally parallel to the center axis of the stem portion. It will be understood that reference herein to passages or other structures extending along directions “generally parallel to,” “generally perpendicular to,” “generally horizontal,” or “generally vertical” are inclusive not only of the particular geometric configuration mentioned, e.g., parallelism or perpendicularity, but are also inclusive of geometric configurations that may be within some angular range (or other range) of the condition specified, e.g., within ±10° of being parallel, perpendicular, horizontal, or vertical (as the case may be). It will be further understood that if terms such as “generally” are required to be removed from such phrases in the claims in spite of the clarity provided above, such removal is not intended to be a surrender of claim scope and the amended phrases should be viewed as being inclusive of both the exact configuration recited as well as other configurations consistent with the guidance provided above.

Showerheads such as those depicted herein may be manufactured of any suitable material, including, for example, aluminum (or alloys thereof), nickel (or alloys thereof), ceramics (such as aluminum oxide), or silicon. The structure of additively manufactured versions of such showerheads may utilize a melted version of such material, e.g., as may be output by an SLM process.

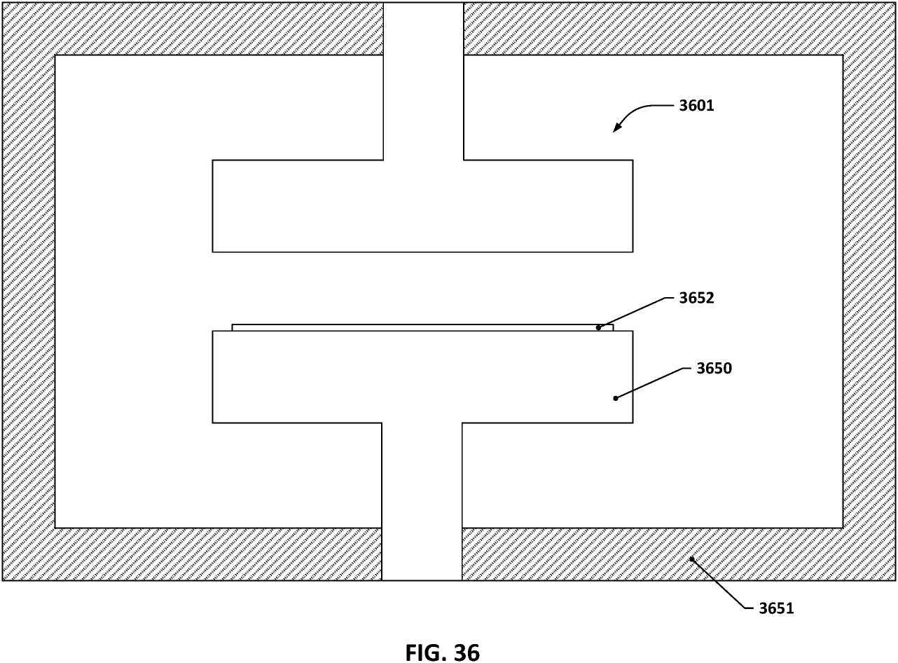

Such showerheads may be used, as mentioned earlier, in a semiconductor processing chamber, such as is schematically shown in FIG. 36. In FIG. 36, a pedestal 3650 may be used to support a wafer 3652 within a chamber 3651. A showerhead 3601, which may be a showerhead such as is described herein, may be positioned over the wafer 3652 and process gases from various process gas sources flowed through the showerhead 3601 and across the wafer 3652 in order to perform desired processing operations.

It will be understood that while the examples herein each included four separate flow paths, other implementations with more or fewer flow paths may also be practiced in accord with the concepts outlined herein. It will also be appreciated that the transverse passage and rhombic lattice pattern arrangements discussed herein may be practice with or without the transverse passage cross-section shapes discussed herein, and vice-versa. Thus, the use of horizontal passages with the cross-section shapes discussed herein in the context of a showerhead may be implemented without necessarily doing so in the context of the rhombic lattice pattern arrangements discussed herein. Similarly, the rhombic lattice pattern arrangements discussed herein may be practiced without necessarily using the cross-sectional shapes discussed herein for the transverse passages.

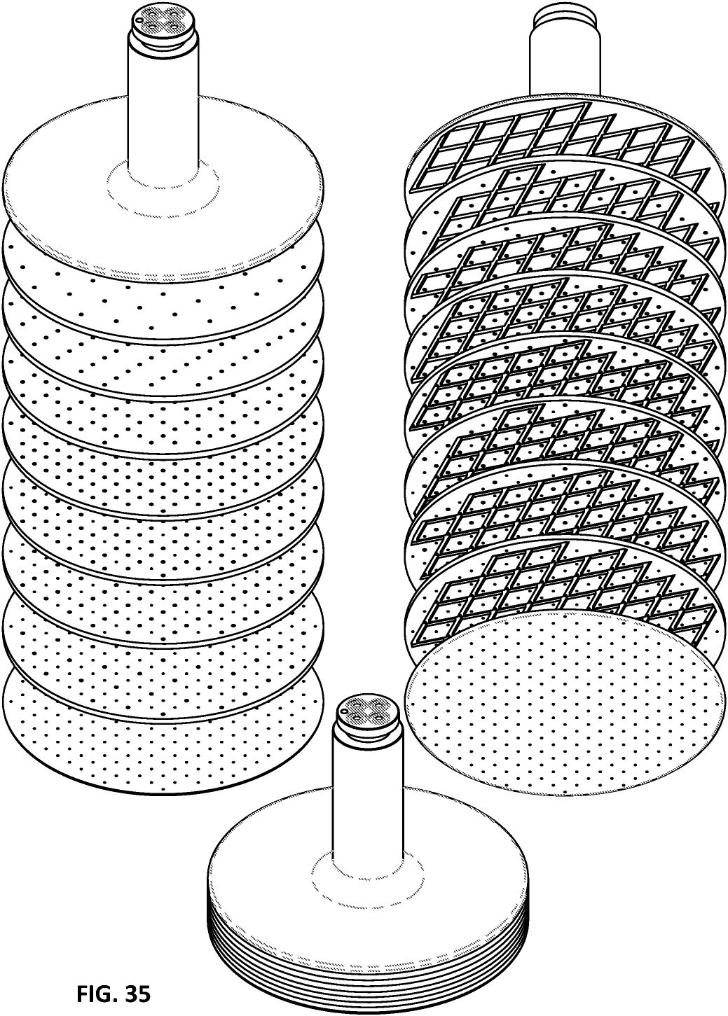

It will also be understood that the showerhead geometries discussed herein, while particularly well-suited for being produced using additive manufacturing techniques, may also be made using more traditional machining techniques. For example, as mentioned earlier, the flow paths of the showerheads discussed herein may also be manufactured by milling transverse passages/channels in rhombic lattice patterns into a plurality of disk-shaped blanks. An example of such an implementation is shown in FIG. 35, which includes two exploded views from different directions, each showing the disk-shaped blanks (the rhombic lattice patterns of channels are visible in the right-hand exploded view), as well as an isometric view of the assembled showerhead, showing the seam lines between disk-shaped blanks.

Each disk-shaped blank may, for example, include a rhombic lattice pattern of channels, as well as through-holes that may be part of riser passages or gas distribution ports. Such disks may then be aligned, stacked together, and brazed, diffusion bonded, or otherwise bonded, adhered, fused, or welded together in order to produce a monolithic showerhead part that has fluidically isolated flow paths within it.

Thus, while the primary focus of the above discussion is on additively manufactured showerheads, it will be understood that the showerhead geometries discussed herein may, with suitable modification, also be used in the context of showerheads manufactured with more traditional, e.g., subtractive, machining techniques. In such alternatives, some features discussed above may be omitted, e.g., the use of triangular or pentagonal cross-section transverse passages may be avoided, and the transverse passages may instead have square, rectangular, semicircular, or other cross-sections that may be obtained with a milling cutter.

It will also be understood that the showerheads discussed herein may be made using a hybrid approach. For example, the showerhead body for a chandelier-type showerhead may be made using additive manufacturing techniques, while the stem for the showerhead may be made using conventional machining techniques and may then be bonded, welded, brazed, or diffusion bonded to the showerhead body.

For clarity, a rhombic lattice pattern, as the phrase is used herein, refers to a pattern in which pattern instances are repeated at locations that align with the intersections between two sets of lines in which the lines within each set of lines are parallel to each other and in which the lines in one set of lines are non-parallel with the lines in the other set of lines. A square grid pattern is an example of a rhombic lattice pattern in which the lines in one set of lines are perpendicular to the lines in the other set of lines; a non-orthogonal lattice pattern is a rhombic lattice pattern in which the lines in one set of lines are at an oblique angle to the lines in the other set of lines. Similarly, the term “rhombic lattice” may be used to refer to an arrangement of generally linear features, e.g., holes or passages, in which those features extend along axes that, when viewed along a direction generally perpendicular to those axes, are arranged as the lines are in a rhombic lattice pattern. It is also to be understood that reference to “lines” with respect to the discussion above is intended to refer to reference lines, e.g., axes, that do not necessarily have to be visible.

The term “isosceles right pentagon” refers to a pentagon having three interior angles that are each 90° and where the remaining two interior angles are each 135°. A shape that is referred to as being generally in the shape of an isosceles right pentagon is a shape having three interior angles that are each within ±10° of 90° and two interior angles that are each within ±10° of 135°.

It will be further understood that reference to shapes being “triangular” or “pentagonal” (or other well-known types of shapes) is intended to be inclusive of exactly those shapes as well as other shapes that are clearly recognizable as such shapes but which include minor deviations from the true geometric definition of such shapes. For example, a triangular shape may have rounded corners, i.e., no sharp vertices, but still clearly be triangular in nature. Similarly, a pentagonal shape may have one or more bowed or slightly curved sides but still generally be easily recognizable as a pentagon.

For the purposes of this disclosure, it will also be understood that the term “fluidically connected” is used with respect to volumes, plenums, holes, etc., that may be connected with one another in order to form a fluidic connection, similar to how the term “electrically connected” is used with respect to components that are connected together to form an electric connection. The term “fluidically interposed,” if used, may be used to refer to a component, volume, plenum, or hole that is fluidically connected with at least two other components, volumes, plenums, or holes such that fluid flowing from one of those other components, volumes, plenums, or holes to the other or another of those components, volumes, plenums, or holes would first flow through the “fluidically interposed” component before reaching that other or another of those components, volumes, plenums, or holes. For example, if a pump is fluidically interposed between a reservoir and an outlet, fluid that flowed from the reservoir to the outlet would first flow through the pump before reaching the outlet. In the context of a sets of fluidic features that are arranged in a fluidically interposed configuration, e.g., a set of fluidic features B are fluidically interposed between one or more fluidic features A and a set of fluidic features C, it will be understood that this refers to an arrangement in which each fluidic feature B is fluidically interposed between at least one fluidic feature A and at least one fluidic feature C; it does not require that each fluidic feature B be fluidically interposed between all fluidic features A and all fluidic features C.

For the purposes of this disclosure, the phrase “fluidically isolated” is used with respect to volumes, plenums, passages, holes, etc. to indicate that one or more such fluidic features is isolated from one or more other such fluidic features. For example, a first set of passages may be fluidically isolated from a second set of passages, in which case gas flowing through the first set of passages may be unable to reach the second set of passages (and vice versa). In some instances, reference may be made to two or more sets of one or more fluidic features or components being fluidically isolated from one another within a particular structure, which is intended to indicate that those fluidic features or components would, if their inlets and/or outlets from that particular structure were to be sealed off, be fluidically isolated from one another. For example, a showerhead may have two separate sets of gas flow passages that do not connect with one another within the showerhead but which may both have gas distribution ports on a common surface of the showerhead—gas could conceivably flow out of the gas distribution ports of one set of gas flow passages and into the gas distribution ports of the other set of gas flow passages, thereby fluidically connecting them, but this would require that the fluidically connecting gas flow be “outside” of the showerhead structure. Thus, the two sets of gas flow passages would still be “fluidically isolated” within the showerhead.

It is to be understood that the phrases “for each <item> of the one or more <items>,” “each <item> of the one or more <items>,” or the like, if used herein, are inclusive of both a single-item group and multiple-item groups, i.e., the phrase “for ... each” is used in the sense that it is used in programming languages to refer to each item of whatever population of items is referenced. For example, if the population of items referenced is a single item, then “each” would refer to only that single item (despite the fact that dictionary definitions of “each” frequently define the term to refer to “every one of two or more things”) and would not imply that there must be at least two of those items. Similarly, the term “set” or “subset” should not be viewed, in itself, as necessarily encompassing a plurality of items—it will be understood that a set or a subset can encompass only one member or multiple members (unless the context indicates otherwise).

The use, if any, of ordinal indicators, e.g., (a), (b), (c)... or the like, in this disclosure and claims is to be understood as not conveying any particular order or sequence, except to the extent that such an order or sequence is explicitly indicated. For example, if there are three steps labeled (i), (ii), and (iii), it is to be understood that these steps may be performed in any order (or even concurrently, if not otherwise contraindicated) unless indicated otherwise. For example, if step (ii) involves the handling of an element that is created in step (i), then step (ii) may be viewed as happening at some point after step (i). Similarly, if step (i) involves the handling of an element that is created in step (ii), the reverse is to be understood.

Terms such as “about,” “approximately,” “substantially,” “nominal,” or the like, when used in reference to quantities or similar quantifiable properties, are to be understood to be inclusive of values within ±10% of the values or relationship specified (as well as inclusive of the actual values or relationship specified), unless otherwise indicated.

It should be appreciated that all combinations of the foregoing concepts (provided such concepts are not mutually inconsistent) are contemplated as being part of the inventive subject matter disclosed herein. In particular, all combinations of claimed subject matter appearing at the end of this disclosure are contemplated as being part of the inventive subject matter disclosed herein. It should also be appreciated that terminology explicitly employed herein that also may appear in any disclosure incorporated by reference should be accorded a meaning most consistent with the particular concepts disclosed herein.

It is to be further understood that the above disclosure, while focusing on a particular example implementation or implementations, is not limited to only the discussed example, but may also apply to similar variants and mechanisms as well, and such similar variants and mechanisms are also considered to be within the scope of this disclosure.

What is claimed is:

1. An apparatus comprising:
a showerhead body including:
one or more sets of first transverse passages extending along paths that are generally parallel to a first plane;
a set of first gas distribution ports extending along paths that are generally perpendicular to the first plane and having first ends that terminate within the showerhead body and second ends terminating at a first exterior surface of the showerhead body; and
one or more first fluidic inlets; wherein:
the one or more sets of first transverse passages includes a first set of first transverse passages,
the first set of first transverse passages is fluidically interposed within the showerhead body between the set of first gas distribution ports and the one or more first fluidic inlets, and
the first set of first transverse passages includes at least one first transverse passage having a cross-section selected from the group consisting of:
a nominally triangular cross-section and a nominally pentagonal cross-section.

2. The apparatus of claim 1, wherein the showerhead body is additively manufactured and has an anisotropic micrograin structure resulting therefrom.

3. The apparatus of claim 1, wherein:
there are two or more sets of first transverse passages,
the two or more sets of first transverse passages further includes a second set of first transverse passages,
the showerhead body further includes one or more sets of first riser passages extending along paths that are generally perpendicular to the first plane,
each set of first riser passages is fluidically interposed between two of the sets of first transverse passages, and
the one or more sets of first riser passages includes a first set of first riser passages fluidically interposed between the first and second sets of first transverse passages.

4. The apparatus of claim 3, wherein each first riser passage in the first set of first riser passages is an extension of a corresponding one of the first gas distribution ports.

5. The apparatus of claim 1, wherein the at least one first transverse passage in the first set of first transverse passages has a nominally triangular cross-section.

6. The apparatus of claim 5, wherein the nominally triangular cross-section has a first side that is generally parallel to the first plane and has second and third sides that each form an included angle of 45° or more with the first side.

7. The apparatus of claim 1, wherein the at least one first transverse passage in the first set of first transverse passages has a nominally pentagonal cross-section.

8. The apparatus of claim 7, wherein the nominally pentagonal cross-section is a pentagon with a first side that is generally parallel to the first plane, second and third sides that are each adjacent to the first side and generally perpendicular to the first plane, and fourth and fifth sides that are, respectively, adjacent to the second and third sides and that each form an angle of 45° or more with respect to the first side.

9. The apparatus of claim 1, wherein the first gas distribution ports are arranged in a non-orthogonal rhombic lattice pattern.

10. The apparatus of claim 9, wherein:
the non-orthogonal rhombic lattice pattern has a maximum pitch along a first axis and a minimum pitch along a second axis perpendicular to the first axis, and
the maximum pitch is generally twice the minimum pitch.

11. The apparatus of claim 1, wherein:
the first transverse passages in the first set of first transverse passages are arranged in two first linear arrays,
each first linear array includes a different plurality of the first transverse passages in the first set of first transverse passages,
the first transverse passages in each first linear array are generally parallel to one another, and
each point of intersection between first transverse passages in the first set of first transverse passages aligns with a corresponding one of the first gas distribution ports.

12. The apparatus of claim 1, wherein the showerhead body further includes:
one or more sets of second transverse passages extending along paths that are generally parallel to the first plane;
a set of second gas distribution ports extending along paths that are generally perpendicular to the first plane and having first ends that terminate within the showerhead body and second ends terminating at the first exterior surface of the showerhead body; and
one or more second fluidic inlets; wherein:
the one or more sets of second transverse passages includes a first set of second transverse passages, and
the first set of second transverse passages is fluidically interposed within the showerhead body between the set of second gas distribution ports and the one or more second fluidic inlets.

13. The apparatus of claim 12, wherein the showerhead body further includes:
one or more sets of third transverse passages extending along paths that are generally parallel to the first plane;
a set of third gas distribution ports extending along paths that are generally perpendicular to the first plane and having first ends that terminate within the showerhead body and third ends terminating at the first exterior surface of the showerhead body; and
one or more third fluidic inlets; wherein:
the one or more sets of third transverse passages includes a first set of third transverse passages, and
the first set of third transverse passages is fluidically interposed within the showerhead body between the set of third gas distribution ports and the one or more third fluidic inlets.

14. The apparatus of claim 13, wherein the showerhead body further includes:
one or more sets of fourth transverse passages extending along paths that are generally parallel to the first plane;
a set of fourth gas distribution ports extending along paths that are generally perpendicular to the first plane and having first ends that terminate within the showerhead body and fourth ends terminating at the first exterior surface of the showerhead body; and
one or more fourth fluidic inlets; wherein:
the one or more sets of fourth transverse passages includes a first set of fourth transverse passages, and
the first set of fourth transverse passages is fluidically interposed within the showerhead body between the set of fourth gas distribution ports and the one or more fourth fluidic inlets.

15. The apparatus of claim 14, wherein:
the first, second, third, and fourth gas distribution ports are arranged in respective first, second, third, and fourth non-orthogonal rhombic lattice patterns,
each of the first, second, third, and fourth non-orthogonal rhombic lattice patterns has a maximum pitch along a corresponding first axis and a minimum pitch along a second axis, and
the first, second, and third non-orthogonal rhombic lattice patterns are each respectively offset along the first axis from the second, third, and fourth non-orthogonal rhombic lattice patterns by a distance of one quarter of the maximum pitch.

16. The apparatus of claim 14, further comprising a stem portion, wherein:
the stem portion extends from a side of the showerhead body opposite the first exterior surface,
the stem portion includes:
one or more first fluidic inlet passages fluidically connected with the one or more first fluidic inlets,
one or more second fluidic inlet passages fluidically connected with the one or more second fluidic inlets,
one or more third fluidic inlet passages fluidically connected with the one or more third fluidic inlets, and
one or more fourth fluidic inlet passages fluidically connected with the one or more fourth fluidic inlets.

17. The apparatus of claim 16, wherein:
the one or more first fluidic inlet passages encircle the one or more second fluidic inlet passages,
the one or more second fluidic inlet passages encircle the one or more third fluidic inlet passages, and
the one or more third fluidic inlet passages encircle the one or more fourth fluidic inlet passages.

18. The apparatus of claim 16, wherein:
the stem portion further includes a first fluidic inlet port,
the one or more first fluidic inlet passages includes a first annular fluidic inlet passage,
the first annular fluidic inlet passage extends along a first axis and has a generally annular cross-section,
the first annular fluidic inlet passage is fluidically interposed between the first fluidic inlet port and the one or more fluidic inlets, and
a flow divider structure is positioned within the first annular fluidic inlet passage such that a first plane is coplanar with the first axis, passes through the first fluidic inlet port, and passes through the flow divider.

19. The apparatus of claim 18, wherein the flow divider structure has a cross-section, when viewed along an axis perpendicular to the first axis, selected from the group consisting of: a lachrymiform shape and a triangular shape.

20. The apparatus of claim 18, wherein surfaces of the flow divider structure facing towards the showerhead body are all angled at 45° or more, or such that planes tangent to those surfaces are at 45° or more, from the first plane.
